(19) United States
(12) Patent Application Publication
(10) Pub. No.: US 2026/0123222 A1
(43) Pub. Date: Apr. 30, 2026

(54) DISPLAY PANEL AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Mengqi WANG, Beijing (CN); Tiaomei ZHANG, Beijing (CN); Wenbo CHEN, Beijing (CN); Jianpeng WU, Beijing (CN); Ziyang YU, Beijing (CN); Zhiliang JIANG, Beijing (CN); Ming HU, Beijing (CN); Haijun QIU, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 19/117,091

(22) PCT Filed: Jan. 16, 2024
(86) PCT No.: PCT/CN2024/072480

§ 371 Date: Mar. 31, 2025

(30) Foreign Application Priority Data
Feb. 1, 2023 (CN) 202310115420.3

(51) Int. Cl. H10K 59/131; H10K 59/121; H10K 59/122; H10K 59/88

(52) U.S. Cl. CPC H10K 59/1315; H10K 59/1213; H10K 59/88; H10K 59/122

(57) ABSTRACT

A display panel includes a base substrate, data lines, first signal lines, second lines, first interconnection portions and a pixel electrode layer. One of the first interconnection portions is connected between a first dummy line and a second dummy line, and an orthographic projection of the first dummy line on the base substrate interests an orthographic projection of the second dummy line on the base substrate. Orthographic projections of the electrode portions on the base substrate do not overlap with orthographic projections of the first interconnection portions on the base substrate.

### CROSS-REFERENCE TO RELATED APPLICATION(S)

This application is a U.S. National Stage of International Application No. PCT/CN2024/072480, filed on Jan. 16, 2024, which claims priority to Chinese Patent Application No. 202310115420.3, filed on Feb. 1, 2023 and entitled “Display Panel and Display Apparatus”, the contents of each are incorporated herein by reference in their entirety as part of this application.

### TECHNICAL FIELD

The present disclosure relates to the display technical field, and in particular to a display panel and a display apparatus.

### BACKGROUND

In Fanout In Panel (FIP) technologies, a display region of a display panel includes a fan-out region and a normal display region outside the fan-out region. Data fan-out line(s) is(are) provided in the fan-out region, and dummy signal line(s) is(are) provided in the normal display region. The dummy signal line(s) can imitate the data fan-out line(s) so that the signal line density of the fan-out region and the signal line density of the normal display region are the same or approximately the same.

Also, the dummy signal lines extending in rows and columns may also be connected through interconnection portion(s) to form signal lines with a grid structure, and the signal lines with the grid structure have a relatively small voltage drop.

However, in the related art, the interconnection portion(s) overlap(overlaps) a part of electrode portions located in a pixel electrode layer, and thus a part of the electrode portions have a partially raised structure. The protrusion causes the electrode portions located in the normal display region and the electrode portions located in the fan-out region to have different reflective effects, thereby causing mura on the display panel when the screen is off.

It should be noted that the information disclosed in the background section is only used to enhance the understanding of the background of the present disclosure, and therefore may include information that does not constitute the prior art known to those of ordinary skill in this art.

### SUMMARY

According to an aspect of the present disclosure, there is provided a display panel. A display region of the display panel includes a fan-out region and a normal display region outside the fan-out region. The display panel further includes: a base substrate, a plurality of data lines, a plurality of first signal lines, a plurality of second signal lines, a plurality of first interconnection portions, and a pixel electrode layer. The plurality of data lines are located in the display region, and orthographic projections of the data lines on the base substrate are spaced apart along a first direction and extend along a second direction, and the first direction intersects the second direction. Orthographic projections of the first signal lines on the base substrate extend along the first direction and are spaced apart along the second direction, a part of the first signal lines located in the fan-out region form a first data fan-out line, and a first signal line located in the normal display region forms a first dummy line, the first data fan-out line is arranged in correspondence with a data line, and the first data fan-out line is connected to a data line corresponding to the first data fan-out line. The plurality of second signal lines are located in a different conductive layer from the first signal lines, and orthographic projections of the second signal lines on the base substrate extend along the second direction and are spaced apart along the first direction, a part of the second signal lines located in the fan-out region forms a second data fan-out line, and a second signal line located in the normal display region forms a second dummy line, the second data fan-out line is arranged in correspondence with a first data fan-out line, and the second data fan-out line is connected to a first data fan-out line corresponding to the second data fan-out line. The plurality of first interconnection portions are located in the normal display region, wherein a first interconnection portion is connected between a first dummy line and a second dummy line, and an orthographic projection of the first dummy line on the base substrate interests an orthographic projection of the second dummy line on the base substrate. The pixel electrode layer includes a plurality of electrode portions, wherein orthographic projections of the electrode portions on the base substrate do not overlap with orthographic projections of the first interconnection portions on the base substrate.

In an example embodiment of the present disclosure, the plurality of first signal lines and the first interconnection portions are located in a same conductive layer, and the plurality of second signal lines are located in a same conductive layer. The conductive layer where the second signal lines are located is located at a side of the conductive layer where the first signal lines is located away from the base substrate. The first interconnection portions and the first dummy line are connected in a same layer, and the first interconnection portions and the second dummy line are connected through a via hole. An orthographic projection of the second dummy line on the base substrate covers an orthographic projection of a first interconnection portion on the base substrate.

In an example embodiment of the present disclosure, the display panel further includes a first source-drain layer and a second source-drain layer. The first source-drain layer is between the base substrate and the pixel electrode layer, and the first source-drain layer includes the first signal lines and the first interconnection portions. The second source-drain layer is between the first source-drain layer and the pixel electrode layer, and the second source-drain layer includes the second signal lines and the data lines.

In an example embodiment of the present disclosure, a part of intersection points of orthographic projections of the first dummy line and the second dummy line on the base substrate are arranged in correspondence with the first interconnection portions, and the first interconnection portion is connected between a first dummy line and a second dummy line which correspond to the first interconnection portion. The number of intersection points of the orthographic projection of the first dummy line on the base substrate and the orthographic projection of the second dummy line on the base substrate is greater than the number of the first interconnection portions.

In an example embodiment of the present disclosure, the display panel includes pixel driving circuits. In the normal display region, a part of the pixel driving circuits are correspondingly provided with one of the first interconnection portions, and n pixel driving circuits which are adjacent in the first direction are correspondingly provided with m first interconnection portions, where n is a positive integer greater than or equal to 2, m is a positive integer greater than or equal to 1, and n is greater than m.

In an example embodiment of the present disclosure, n is equal to 4, m is equal to 3, the first direction is a row direction, and the second direction is a column direction. The plurality of electrode portions include a first electrode portion, a second electrode portion, a third electrode portion, and a fourth electrode portion. Among a plurality of electrode portions connected to pixel driving circuits in a same row, the first electrode portion, the second electrode portion, the third electrode portion, and the fourth electrode portion are alternately distributed in sequence in the row direction. In two adjacent columns of pixel driving circuits, the first electrode portion and the third electrode portion are connected to a same column of pixel driving circuits, and the first electrode portion and the third electrode portion connected to the same column of pixel driving circuits are alternately distributed in sequence in the column direction, the second electrode portion and the fourth electrode portion are connected to another column of pixel driving circuits, and the second electrode portion and the fourth electrode portion connected to a same column of pixel driving circuits are alternately distributed in sequence in the column direction. Among four pixel driving circuits which are adjacent in the first direction, a pixel driving circuit corresponding to the first electrode portion is correspondingly provided with a first interconnection portion, a pixel driving circuit corresponding to the second electrode portion is correspondingly provided with a first interconnection portion, and a pixel driving circuit corresponding to the third electrode portion is correspondingly provided with a first interconnection portion.

In an example embodiment of the present disclosure, the pixel driving circuit includes a driving transistor, a second transistor and a fifth transistor, a first electrode of the second transistor is connected to a gate of the driving transistor, a second electrode of the second transistor is connected to a second electrode of the driving transistor, a first electrode of the fifth transistor is connected to a power supply line, and a second electrode of the fifth transistor is connected to a first electrode of the driving transistor. The display panel further includes: a first gate layer and a second source-drain layer. The first gate layer is between the base substrate and the pixel electrode layer, and the first gate layer includes a first conductive portion and a gate line, an orthographic projection of the gate line on the base substrate extends along the first direction, the first conductive portion is used to form the gate of the driving transistor, and a partial structure of the gate line is used to form a gate of the second transistor. The second source-drain layer is between the first gate layer and the pixel electrode layer. The second source-drain layer includes the power supply line and the data line, and an orthographic projection of the power supply line on the base substrate and the orthographic projection of the data line on the base substrate extend along the second direction. The first dummy line is arranged in correspondence with a pixel driving circuit, and in the pixel driving circuit and the first dummy line which mutually correspond to each other, an orthographic projection of the first dummy line on the base substrate is located at a side of an orthographic projection of the first conductive portion on the base substrate away from an orthographic projection of the gate line on the base substrate. The second dummy line is arranged in correspondence with a pixel driving circuit, and in the pixel driving circuit and the second dummy line which mutually correspond to each other, an orthographic projection of the second dummy line on the base substrate is located at a side of the orthographic projection of the power supply line on the base substrate away from an orthographic projection of the data line on the base substrate. A first interconnection portion is arranged in correspondence with a first dummy line and a second dummy line which are directly connected to the first interconnection portion, and a pixel driving circuit corresponding to a same group of the first dummy line and the second dummy line is arranged in correspondence with the first interconnection portion.

In an example embodiment of the present disclosure, the conductive layer where the first signal lines are located further includes: a first dummy via contact portion and a second dummy via contact portion. The first dummy via contact portion is located in the fan-out region, an intersection point of orthographic projections of a first signal line and a second signal line located in the fan-out region on the base substrate is arranged in correspondence with the first dummy via contact portion, the first dummy via contact portion is insulated from a first signal line, and a second signal line is connected, through a via hole, to a first dummy via contact portion corresponding to the second signal line. The second dummy via contact portion is located in the normal display region, wherein among intersection points of orthographic projections of first dummy lines and second dummy lines on the base substrate, an intersection point which is not arranged in correspondence with a first interconnection portion is arranged in correspondence with the second dummy via contact portion, the second dummy via contact portion is insulated from the first dummy line, and a second dummy line is connected to, through a via hole, a second dummy via contact portion which corresponds to the second dummy line.

In an example embodiment of the present disclosure, the first interconnection portion includes a first via contact portion, and the first via contact portion is connected to a second dummy line through a via hole. The first dummy via contact portion, the second dummy via contact portion, and the first via contact portion form a via contact portion. The minimum distance between orthographic projections of adjacent via contact portions on the base substrate in the first direction is S1, and the maximum distance between the orthographic projections of adjacent via contact portions on the base substrate in the first direction is S2, wherein (S2−S1)/S1 is greater than or equal to 0 and smaller than or equal to 0.2. The minimum distance between the orthographic projections of adjacent via contact portions on the base substrate in the second direction is S3, and the maximum distance between the orthographic projections of adjacent via contact portions on the base substrate in the second direction is S4, wherein (S4−S3)/S3 is greater than or equal to 0 and smaller than or equal to 0.2.

In an example embodiment of the present disclosure, an orthographic projection of the first dummy via contact portion on the base substrate at least partially overlaps with an orthographic projection of the electrode portion on the base substrate. An orthographic projection of the second dummy via contact portion on the base substrate at least partially overlaps with the orthographic projection of the electrode portion on the base substrate.

In an example embodiment of the present disclosure, the display panel further includes a pixel driving circuit and a light-emitting unit, and the pixel driving circuit is connected to a first electrode of the light-emitting unit. The display panel further includes: a common electrode layer, wherein the common electrode layer is used to form a second electrode of the light-emitting unit. The first dummy line and the second dummy line are connected to the common electrode layer.

In an example embodiment of the present disclosure, the display panel further includes a frame region around the display region, the frame region including a first frame region and a second frame region arranged opposite to each other in the first direction, and a third frame region and a fourth frame region arranged opposite to each other in the second direction. The display panel further includes: an electrode ring, wherein the electrode ring is located in the frame region and connected to the common electrode layer, at least partial structure of the electrode ring located in the first frame region is connected to the first dummy line, at least partial structure of the electrode ring located in the second frame region is connected to the first dummy line, at least partial structure of the electrode ring located in the third frame region is connected to the second dummy line, and at least partial structure of the electrode ring located in the fourth frame region is connected to the second dummy line.

In an example embodiment of the present disclosure, the minimum distance between orthographic projections of two adjacent first signal lines on the base substrate in the second direction is S5, and the maximum distance between the orthographic projections of two adjacent first signal lines on the base substrate in the second direction is S6, wherein (S6−S5)/S5 is greater than or equal to 0 and smaller than or equal to 0.2; and/or, wherein the minimum distance between the orthographic projections of two adjacent second signal lines on the base substrate in the first direction is S7, and the maximum distance between the orthographic projections of two adjacent second signal lines on the base substrate in the first direction is S8, wherein (S8−S7)/S7 is greater than or equal to 0 and smaller than or equal to 0.2.

In an example embodiment of the present disclosure, the display panel further includes a light-emitting unit and a pixel driving circuit for driving the light-emitting unit, the pixel driving circuit includes a driving transistor, a fourth transistor, and a seventh transistor, a first electrode of the fourth transistor is connected to a data line, a second electrode of the fourth transistor is connected to a first electrode of the driving transistor, a first electrode of the seventh transistor is connected to a second initialization signal line, and a second electrode of the seventh transistor is connected to a first electrode of the light-emitting unit. The display panel further includes: an active layer and a first gate layer. The active layer is between the base substrate and the pixel electrode layer, wherein the active layer includes a seventh active portion and a fourth active portion, the seventh active portion is used to form a channel region of the seventh transistor, and the fourth active portion is used to form a channel region of the fourth transistor. The first gate layer is between the active layer and the pixel electrode layer, wherein the first gate layer includes a second reset signal line, an orthographic projection of the second reset signal line on the base substrate covers an orthographic projection of the fourth active portion on the base substrate and an orthographic projection of the seventh active portion on the base substrate, a partial structure of the second reset signal line is used to form a gate of the seventh transistor, and a partial structure of the second reset signal line is used to form a gate of the fourth transistor.

In an example embodiment of the present disclosure, the active layer further includes: a third active portion, an eighth active portion and a ninth active portion. The third active portion is used to form a channel region of the driving transistor. The eighth active portion is connected to the fourth active portion. The ninth active portion is connected to the third active portion. The display panel further includes: a first source-drain layer. The first source-drain layer is between the first gate layer and the pixel electrode layer, wherein the first source-drain layer includes a first bridging portion, and the first bridging portion is connected to the eighth active portion and the ninth active portion through via holes.

first source-drain layer the display panel further includes a pixel driving circuit, the pixel driving circuit includes a driving transistor, a first transistor, and a second transistor, a first electrode of the first transistor is connected to a first initialization signal line, a second electrode of the first transistor is connected to a gate of the driving transistor, a first electrode of the second transistor is connected to the gate of the driving transistor, and a second electrode of the second transistor is connected to a second electrode of the driving transistor. The display panel further includes: an active layer and a second gate layer. The active layer is between the base substrate and the pixel electrode layer, wherein the active layer includes a first active portion, a tenth active portion, a first active sub-portion, a second active sub-portion, and a third active sub-portion connected between the first active sub-portion and the second active sub-portion, the first active portion is used to form a channel region of the first transistor, the first active sub-portion and the second active sub-portion are used to form a channel region of the second transistor, and the tenth active portion is connected between the first active portion and the first active sub-portion. The second gate layer is between the active layer and the pixel electrode layer, wherein the second gate layer includes the first initialization signal line, a first protrusion, and a second protrusion, the first protrusion is connected to the first initialization signal line, and the second protrusion is connected to the first initialization signal line. An orthographic projection of the first protrusion on the base substrate at least partially overlaps with an orthographic projection of the third active sub-portion on the base substrate, and an orthographic projection of the second protrusion on the base substrate at least partially overlaps with the orthographic projection of the tenth active portion on the base substrate.

According to an aspect of the present disclosure, there is provided a display panel. A display region of the display panel includes a fan-out region and a normal display region outside the fan-out region. The display panel further includes: a base substrate, a plurality of data lines, a plurality of first signal lines, a plurality of second signal lines and a plurality of first interconnection portions. The plurality of data lines are located in the display region, and orthographic projections of the data lines on the base substrate are spaced apart along a first direction and extend along a second direction, and the first direction intersects the second direction. Orthographic projections of the first signal lines on the base substrate extend along the first direction and are spaced apart along the second direction, a part of the first signal lines located in the fan-out region form a first data fan-out line, and a first signal line located in the normal display region forms a first dummy line, the first data fan-out line is arranged in correspondence with a data line, and the first data fan-out line is connected to a data line corresponding to the first data fan-out line. The plurality of second signal lines are located in a different conductive layer from the first signal lines, wherein orthographic projections of the second signal lines on the base substrate extend along the second direction and are spaced apart along the first direction, a part of the second signal lines located in the fan-out region forms a second data fan-out line, and a second signal line located in the normal display region forms a second dummy line, the second data fan-out line is arranged in correspondence with a first data fan-out line, and the second data fan-out line is connected to a first data fan-out line corresponding to the second data fan-out line. The plurality of first interconnection portions are located in the normal display region, wherein a first interconnection portion is connected between a first dummy line and a second dummy line, and an orthographic projection of the first dummy line on the base substrate interests an orthographic projection of the second dummy line on the base substrate. The display panel further includes pixel driving circuits, and in the normal display region, a part of the pixel driving circuits is correspondingly provided with one first interconnection portion; and n pixel driving circuits which are adjacent in the first direction are correspondingly provided with m first interconnection portions, where n is a positive integer greater than or equal to 2, m is a positive integer greater than or equal to 1, and n is greater than m.

In an example embodiment of the present disclosure, n is equal to 4, m is equal to 3, the first direction is a row direction, and the second direction is a column direction. The display panel further includes: a pixel electrode layer. The pixel electrode layer includes a plurality of electrode portions. The plurality of electrode portions include a first electrode portion, a second electrode portion, a third electrode portion, and a fourth electrode portion. Among a plurality of electrode portions connected to pixel driving circuits in a same row, the first electrode portion, the second electrode portion, the third electrode portion, and the fourth electrode portion are alternately distributed in sequence in the row direction. In two adjacent columns of pixel driving circuits, the first electrode portion and the third electrode portion are connected to a same column of pixel driving circuits, and the first electrode portion and the third electrode portion connected to the same column of pixel driving circuits are alternately distributed in sequence in the column direction, the second electrode portion and the fourth electrode portion are connected to another column of pixel driving circuits, and the second electrode portion and the fourth electrode portion connected to a same column of pixel driving circuits are alternately distributed in sequence in the column direction. Among four pixel driving circuits which are adjacent in the first direction, a pixel driving circuit corresponding to the first electrode portion is correspondingly provided with a first interconnection portion, a pixel driving circuit corresponding to the second electrode portion is correspondingly provided with a first interconnection portion, and a pixel driving circuit corresponding to the third electrode portion is correspondingly provided with a first interconnection portion.

In an example embodiment of the present disclosure, the pixel driving circuit includes a driving transistor, a second transistor and a fifth transistor, a first electrode of the second transistor is connected to a gate of the driving transistor, a second electrode of the second transistor is connected to a second electrode of the driving transistor, a first electrode of the fifth transistor is connected to a power supply line, and a second electrode of the fifth transistor is connected to a first electrode of the driving transistor. The display panel further includes: a first gate layer, and a second source-drain layer. The first gate layer is located at a side of the base substrate, wherein the first gate layer includes a first conductive portion and a gate line, an orthographic projection of the gate line on the base substrate extends along the first direction, the first conductive portion is used to form the gate of the driving transistor, and a partial structure of the gate line is used to form a gate of the second transistor. The second source-drain layer is located at a side of the first gate layer away from the base substrate, wherein the second source-drain layer includes the power supply line and the data line, and an orthographic projection of the power supply line on the base substrate and the orthographic projection of the data line on the base substrate extend along the second direction. The first dummy line is arranged in correspondence with a pixel driving circuit, and in the pixel driving circuit and the first dummy line which mutually correspond to each other, an orthographic projection of the first dummy line on the base substrate is located at a side of an orthographic projection of the first conductive portion on the base substrate away from an orthographic projection of the gate line on the base substrate. The second dummy line is arranged in correspondence with a pixel driving circuit, and in the pixel driving circuit and the second dummy line which mutually correspond to each other, an orthographic projection of the second dummy line on the base substrate is located at a side of the orthographic projection of the power supply line on the base substrate away from an orthographic projection of the data line on the base substrate. A first interconnection portion is arranged in correspondence with a first dummy line and a second dummy line which are directly connected to the first interconnection portion, and a pixel driving circuit corresponding to a same group of the first dummy line and the second dummy line is arranged in correspondence with the first interconnection portion.

According to an aspect of the present disclosure, there is provided a display apparatus. The display apparatus includes the display panel described above.

It is to be understood that the foregoing general description and the following detailed description are illustrative and explanatory only and are not restrictive of the present disclosure.

### BRIEF DESCRIPTION OF THE DRAWINGS

The accompanying drawings herein, which are incorporated into the description and constitute a part of the description, illustrate embodiments consistent with the present disclosure, and are used together with the description to explain principles of the present disclosure. Obviously, the accompanying drawings described below are only some embodiments of the present disclosure and for those of ordinary skill in this art, other accompanying drawings can be obtained based on these accompanying drawings without creative work.

FIG. 1 is a schematic structural diagram of an example embodiment of a display panel in the related art;

FIG. 2 is a structural layout diagram of a normal display region in FIG. 1;

FIG. 3 is a structural layout diagram of a first source-drain layer in FIG. 2;

FIG. 4 is a structural layout diagram of a second source-drain layer in FIG. 2;

FIG. 5 is a structural layout diagram of a pixel electrode layer in FIG. 2;

FIG. 6 is a structural layout diagram of the first source-drain layer and the second source-drain layer in FIG. 2;

FIG. 7 is a schematic structural diagram of a display panel according to an example embodiment of the present disclosure;

FIG. 8 is a structural layout diagram of a normal display region in FIG. 7;

FIG. 9 is a structural layout diagram of a first source-drain layer in FIG. 8;

FIG. 10 is a structural layout diagram of a second source-drain layer in FIG. 8;

FIG. 11 is a structural layout diagram of a pixel electrode layer and a pixel definition layer in FIG. 8;

FIG. 12 is a structural layout diagram of the first source-drain layer and the second source-drain layer in FIG. 8;

FIG. 13 is a structural layout diagram of a partial region K1 of a fan-out region in FIG. 7;

FIG. 14 is a structural layout diagram of the first source-drain layer in FIG. 13;

FIG. 15 is a structural layout diagram of the second source-drain layer in FIG. 13;

FIG. 16 is a structural layout diagram of the pixel electrode layer and the pixel definition layer in FIG. 13;

FIG. 17 is a structural layout diagram of the first source-drain layer and the second source-drain layer in FIG. 13;

FIG. 18 is a schematic structural diagram of a pixel driving circuit in a display panel according to an example embodiment of the present disclosure;

FIG. 19 is a timing diagram of signals on respective nodes in a driving method of the pixel circuit shown in FIG. 18;

FIG. 20 is a structural layout diagram of a display panel according to an example embodiment of the present disclosure;

FIG. 21 is a structural layout diagram of an active layer in FIG. 20;

FIG. 22 is a structural layout diagram of a first gate layer in FIG. 20;

FIG. 23 is a structural layout diagram of a second gate layer in FIG. 20;

FIG. 24 is a structural layout diagram of a first source-drain layer in FIG. 20;

FIG. 25 is a structural layout diagram of a second source-drain layer in FIG. 20;

FIG. 26 is a structural layout diagram of the active layer and the first gate layer in FIG. 20;

FIG. 27 is a structural layout diagram of the active layer and the first gate layer and the second gate layer in FIG. 20;

FIG. 28 is a structural layout diagram of the active layer and the first gate layer, the second gate layer, and the first source-drain layer in FIG. 20;

FIG. 29 is a partial cross-sectional view of the display panel shown in FIG. 20 taken along a dotted line BB;

FIG. 30 is a partial layout structure of a region K3 in FIG. 7;

FIG. 31 is a structural layout diagram of the first source-drain layer in FIG. 30;

FIG. 32 is a structural layout diagram of the second source-drain layer in FIG. 30;

FIG. 33 is a partial layout structure of a region K4 in FIG. 7;

FIG. 34 is a structural layout diagram of the first source-drain layer in FIG. 33;

FIG. 35 is a structural layout diagram of the second source-drain layer in FIG. 33;

FIG. 36 is a partial layout structure of a region K5 in FIG. 7;

FIG. 37 is a structural layout diagram of the first gate layer in FIG. 36;

FIG. 38 is a structural layout diagram of the second gate layer in FIG. 36;

FIG. 39 is a structural layout diagram of the first source-drain layer in FIG. 36;

FIG. 40 is a structural layout diagram of the second source-drain layer in FIG. 36;

FIG. 41 is a structural layout diagram of the first gate layer and the second gate layer in FIG. 36;

FIG. 42 is a structural layout of the first gate layer, the second gate layer, and the first source-drain layer in FIG. 36.

### DETAILED DESCRIPTION

Example embodiments will now be described more fully with reference to the accompanying drawings. However, example embodiments can be implemented in a variety of forms and should not be construed as limited to the examples set forth herein; rather, these embodiments are provided so that the present disclosure will be more comprehensive and complete and will fully convey the concepts of the example embodiments to those skilled in the art. The same reference numerals in the figures represent the same or similar structures, and thus their detailed description will be omitted.

The terms “one”, “a/an”, and “said” are used to indicate the presence of one or more elements/components/etc.; the terms “comprising/including” and “having” are used to indicate an open-ended inclusive meaning and mean that additional elements/components/etc. may be present in addition to the listed elements/components/etc.

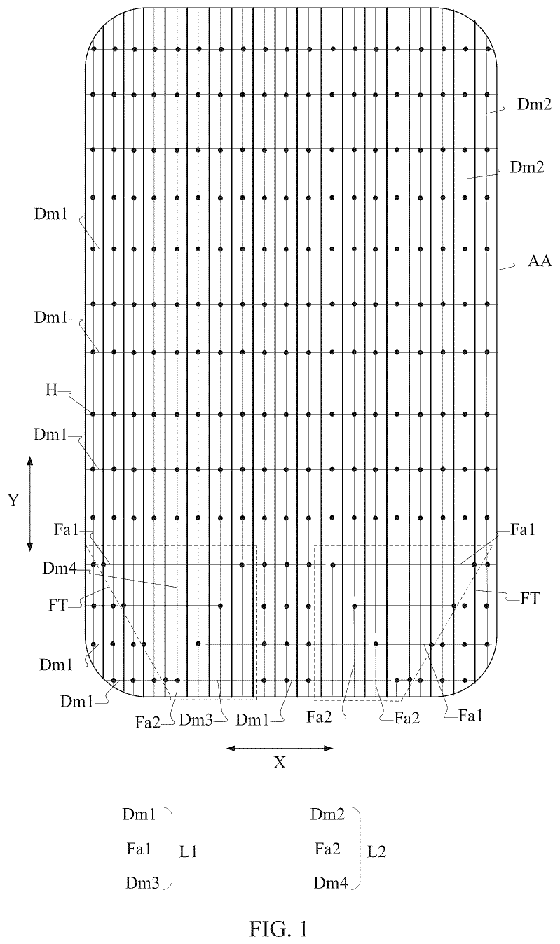

As shown in FIG. 1, it is a schematic structural diagram of an example embodiment of a display panel in the related art. The display panel may include a display region AA, and the display region AA may include a fan-out region FT and a normal display region outside the fan-out region. The display panel may further include a base substrate, a plurality of data lines Da, a plurality of first signal lines L1, and a plurality of second signal lines L2. The plurality of data lines Da are located in the display region AA, and the orthographic projections of the data lines Da on the base substrate are spaced apart along a first direction X and extend along a second direction Y. The first direction X intersects the second direction Y. For example, the first direction X may be a row direction, and the second direction Y may be a column direction. The orthographic projections of the plurality of first signal lines L1 on the base substrate extend along the first direction X and are spaced apart along the second direction Y. A part of the first signal lines L1 located in the fan-out region FT forms first data fan-out line(s) Fa1, a part of the first signal lines L1 located in the fan-out region FT forms third dummy line(s) Dm3, and the first signal line(s) L1 located in the normal display region forms(form) first dummy line(s) Dm1. The first data fan-out line(s) Fa1 is(are) arranged in correspondence with the data line(s) Da. A first data fan-out line Fa1 is connected to a data line Da corresponding to the first data fan-out line Fa1. The plurality of second signal lines L2 are located in a different conductive layer from the first signal lines L1. The orthographic projections of the second signal lines L2 on the base substrate extend along the second direction Y and are spaced apart along the first direction X. A part of the second signal lines L2 located in the fan-out region FT forms(form) second data fan-out line(s) Fa2, a part of the second signal lines L2 located in the fan-out region FT forms(form) fourth dummy line(s) Dm4, and the second signal line(s) L2 located in the normal display region forms(form) second dummy line(s) Dm2. The second data fan-out lines Fa2 are arranged in correspondence with the first data fan-out lines Fa1. A second data fan-out line Fa2 is connected to a first data fan-out line Fa1 corresponding to the second data fan-out line Fa2.

As shown in FIG. 1, a first dummy line Dm1 is connected to a third dummy line Dm3, and a second dummy line Dm2 is connected to a fourth dummy line Dm4. Third dummy line Dm3 are spaced apart from the first data fan-out lines Fa1, and the fourth dummy lines Dm4 are spaced apart from the second data fan-out line Fa2. The first dummy lines Dm1, the second dummy lines Dm2, the third dummy lines Dm3, and the fourth dummy lines Dm4 can make the distribution density of the first signal lines L1 and the second signal lines L2 in the normal display region to be the same with that in the fan-out region FT, thereby improving the mura of the display panel when the screen is off.

As shown in FIG. 1, in the related art, a first dummy line Dm1 and a second dummy line Dm2 whose orthographic projections on the base substrate intersect with each other can be connected through a via hole H (the black circle). The first dummy lines Dm1 and the second dummy lines Dm2 may be connected to a common electrode layer in the display panel. The first dummy lines Dm1 and the second dummy lines Dm2 of a grid structure can reduce the self-resistance of the common electrode layer, thereby reducing the voltage difference at different positions of the common electrode layer and improving the display uniformity of the display panel.

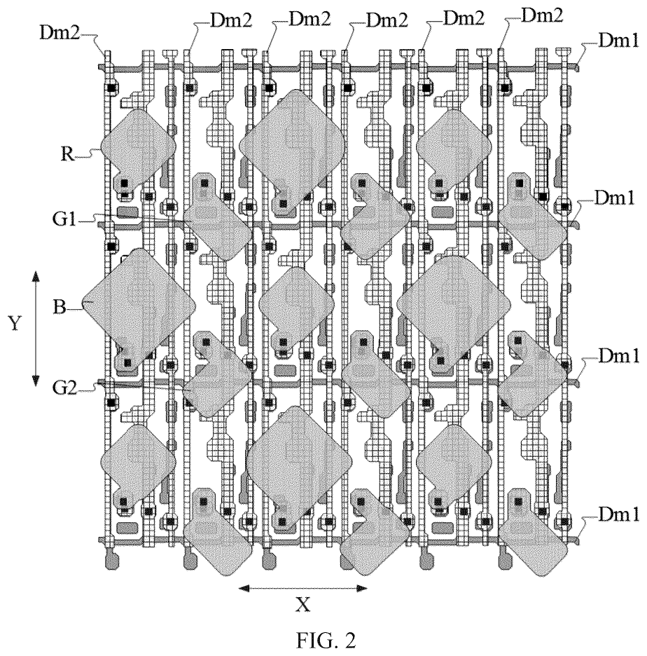

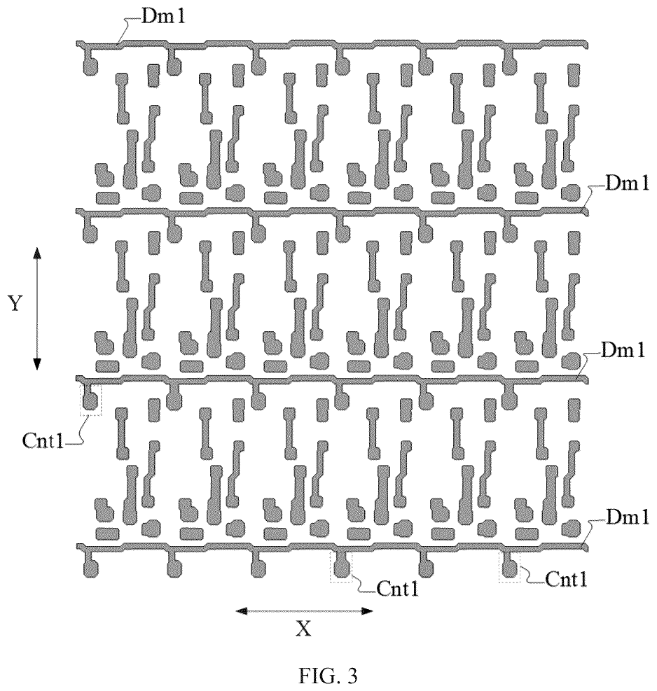

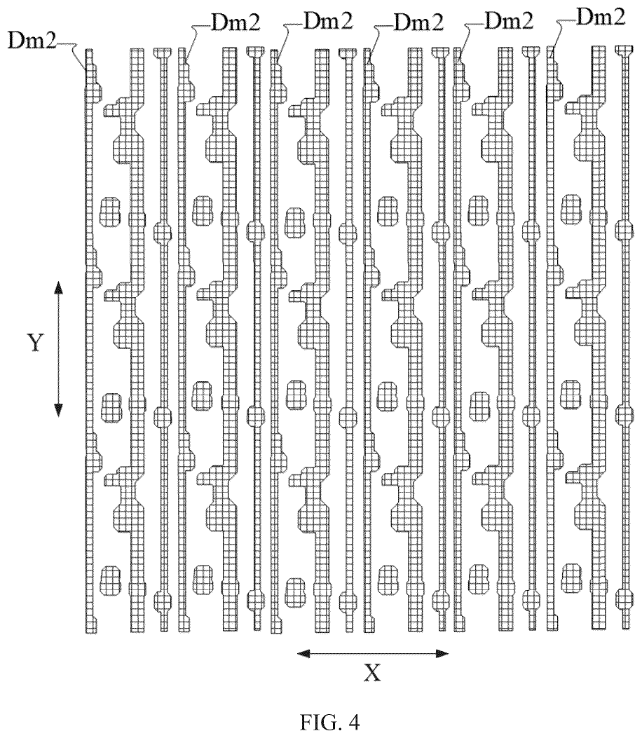

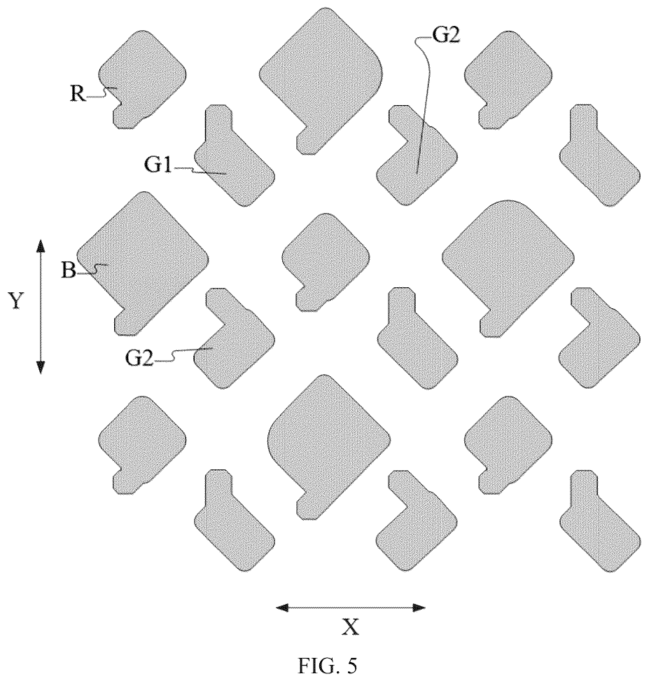

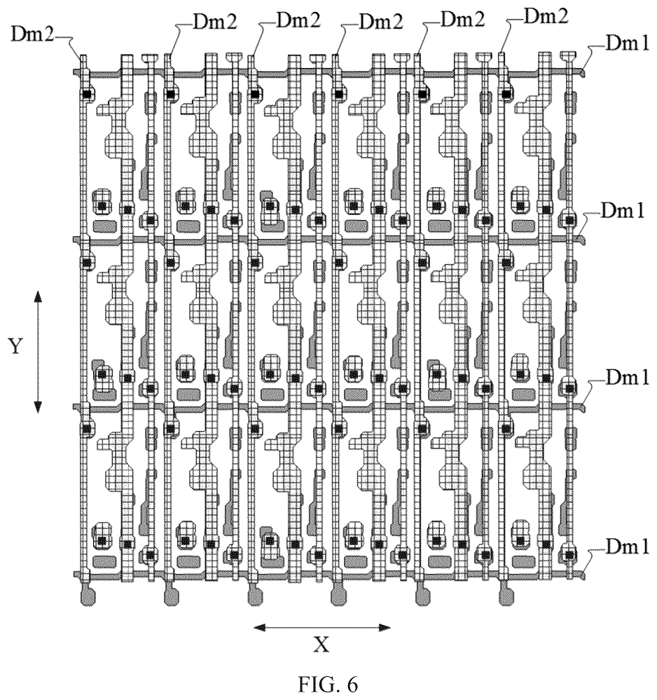

As shown in FIGS. 2 to 6, FIG. 2 is a structural layout diagram of the normal display region in FIG. 1. The display panel may include a first source-drain layer, a second source-drain layer, and a pixel electrode layer stacked in sequence. FIG. 3 is a structural layout diagram of the first source-drain layer in FIG. 2. FIG. 4 is a structural layout diagram of the second source-drain layer in FIG. 2. FIG. 5 is a structural layout diagram of the pixel electrode layer in FIG. 2. FIG. 6 is a structural layout diagram of the first source-drain layer and the second source-drain layer in FIG. 2.

The first dummy lines Dm1 are located in the first source-drain layer, and the second dummy lines Dm2 are located in the second source-drain layer. The first source-drain layer may further include first interconnection portion(s) Cnt1. A first interconnection portion Cnt1 is connected to a first dummy line Dm1, and a second dummy line Dm2 is connected to the first interconnection portion Cnt1 through a via hole (the black square indicates the position of the via hole) to connect to the first dummy line Dm1 which intersects the second dummy line Dm2. However, as shown in FIG. 2, the pixel electrode layer includes a first electrode portion R, a second electrode portion G1, a third electrode portion B, and a fourth electrode portion G2. The orthographic projection of the fourth electrode portion G2 on the base substrate overlaps with the orthographic projection of a first interconnection portion Cnt1 on the base substrate, and the fourth electrode portion G2 overlapping with the first interconnection portion Cnt1 is locally raised at the overlapping position. Also, since the first interconnection portion is not provided in the fan-out region, a fourth electrode portion G2 in the fan-out region and a fourth electrode portion G2 in the normal display region have different reflective properties, which causes the display panel to have mura when the screen is off.

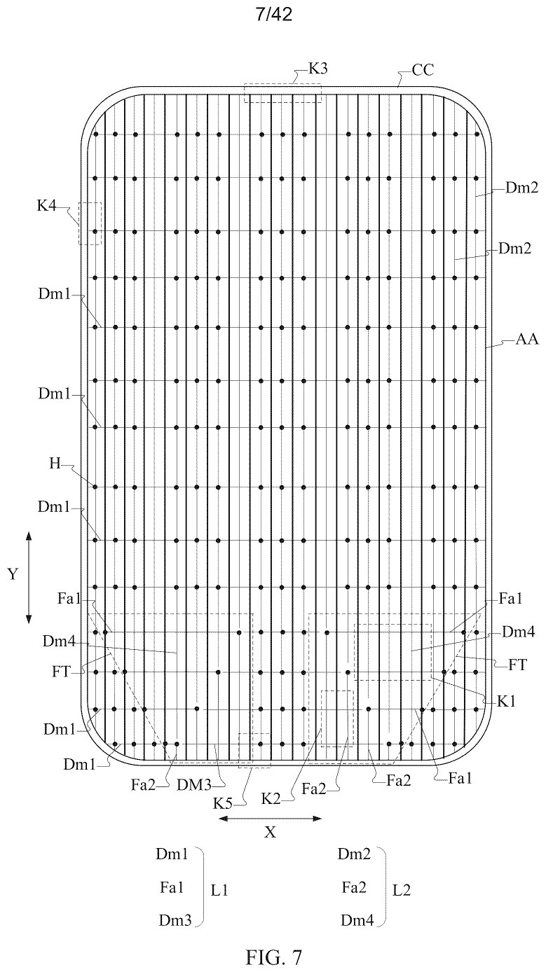

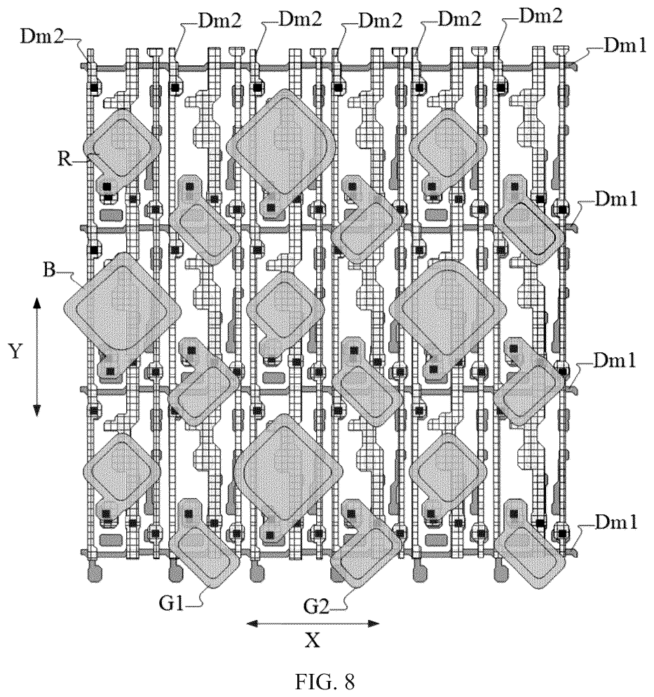

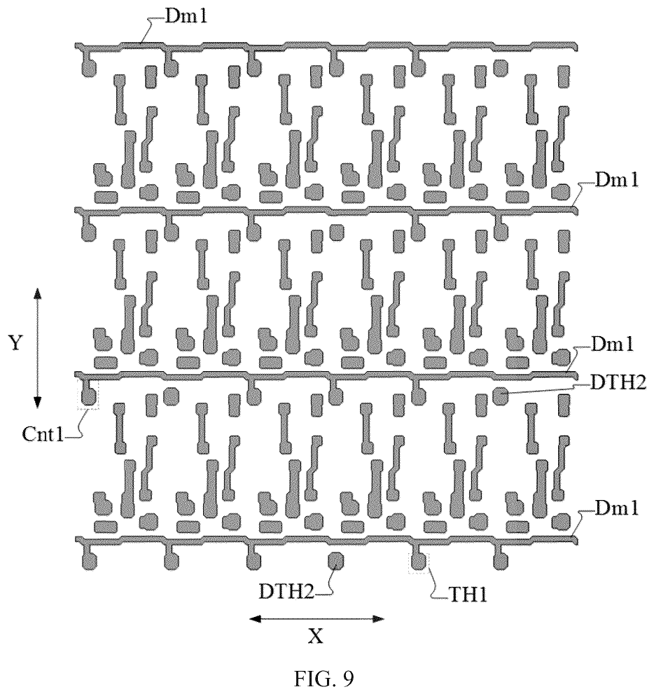

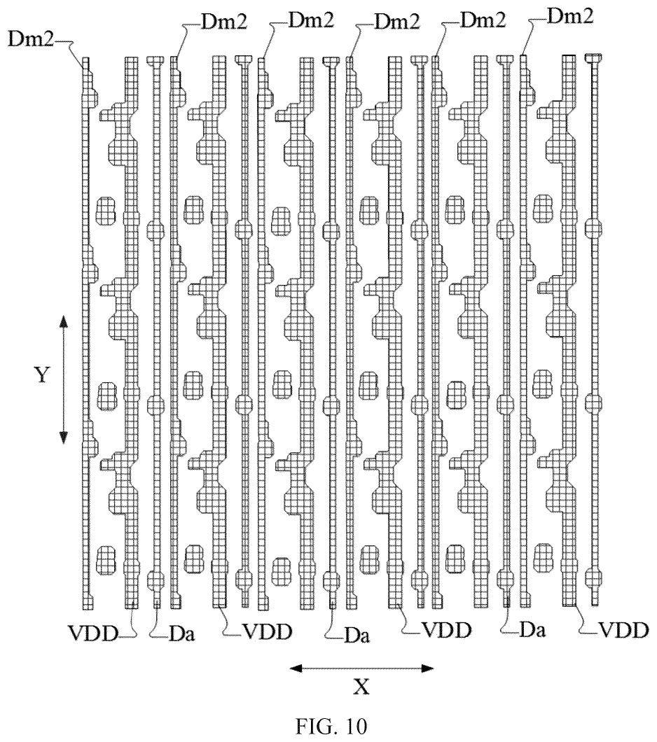

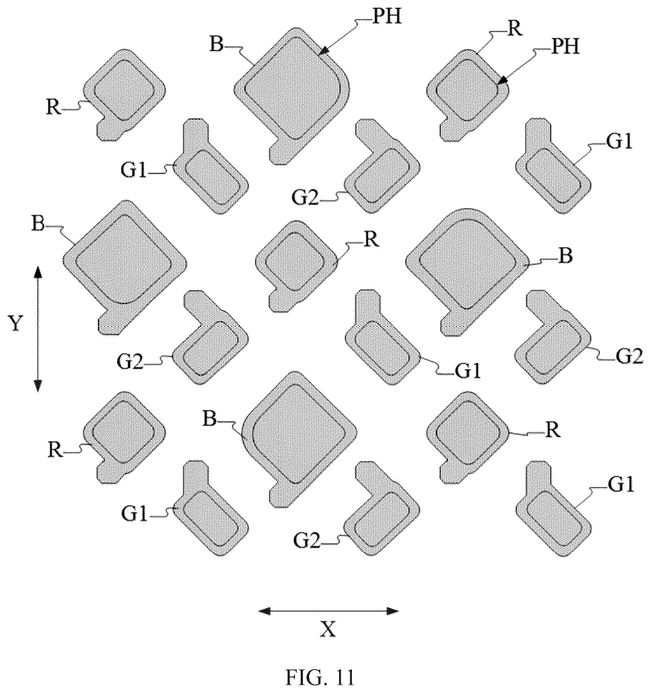

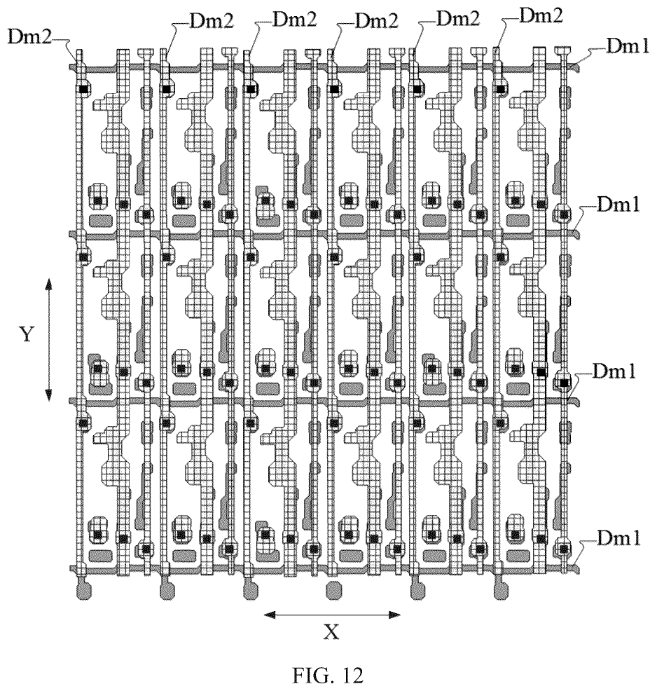

Based on this, an example embodiment provides a display panel, as shown in FIGS. 7 to 11. FIG. 7 is a schematic structural diagram of a display panel according to an example embodiment of the present disclosure. The display panel may include a first source-drain layer, a second source-drain layer, a pixel electrode layer, and a pixel definition layer stacked in sequence. FIG. 8 is a structural layout diagram of a normal display region in FIG. 7. FIG. 9 is a structural layout diagram of the first source-drain layer in FIG. 8. FIG. 10 is a structural layout diagram of the second source-drain layer in FIG. 8. FIG. 11 is a structural layout diagram of the pixel electrode layer and the pixel definition layer in FIG. 8. FIG. 12 is a structural layout diagram of the first source-drain layer and the second source-drain layer in FIG. 8.

Compared with the display panel shown in FIG. 1, in the display panel shown in FIG. 7, a part of intersection points of the orthographic projections of the first dummy lines Dm1 and the second dummy lines Dm2 on the base substrate are arranged in correspondence with first interconnection portion(s) Cnt1. A first interconnection portion Cnt1 is connected between a first dummy line and a second dummy line corresponding to the first interconnection portion Cnt1. A first interconnection portion Cnt1 is arranged in correspondence with a first dummy line and a second dummy line which form an intersection point corresponding the first interconnection portion Cnt1. The number of intersection points of the orthographic projections of the first dummy lines Dm1 on the base substrate and the orthographic projections of the second dummy lines Dm2 on the base substrate is greater than the number of the first interconnection portion(s) Cnt1. That is, the display panel shown in FIG. 7 removes a part of the first interconnection portion(s) in the normal display region, so that the orthographic projections of the first interconnection portions on the base substrate do not overlap with the orthographic projection of any electrode portion on the base substrate. This arrangement can provide improvement to the problem of mura on the display panel when the screen is off.

As shown in FIGS. 8 and 11, a plurality of pixel openings PH may be formed in the pixel definition layer. The pixel openings PH and the electrode portions are arranged correspondingly. The orthographic projection of a pixel openings PH on the base substrate is located on the orthographic projection of a corresponding electrode portion on the base substrate. The orthographic projection area of the electrode portion on the base substrate is slightly larger than the orthographic projection area of the pixel opening PH on the base substrate.

It should be understood that in other example embodiments, the orthographic projection overlapping between the first interconnection portion(s) and the electrode portion(s) on the base substrate may be avoided by other methods. For example, the overlapping of the first interconnection portion(s) and the electrode portion(s) may be avoided by changing the shape(s) or position(s) of the first interconnection portion(s). In addition, in other example embodiments, the first signal lines L1 may be located in other conductive layer(s), and the second signal lines L2 may be located in other conductive layer(s), and the conductive layer where the second signal lines are located is arranged at a side of the conductive layer where the first signal lines are located away from the base substrate. The first interconnection portions and the first dummy lines may be connected in the same layer, and the first interconnection portions and the second dummy lines may be connected through via holes.

As shown in FIG. 8, the orthographic projection of a second dummy line Dm2 on the base substrate may cover the orthographic projection of a first interconnection portion Cnt1 on the base substrate. This arrangement can ensure that the first interconnection portion Cnt1 does not affect the distribution density of a light-shielding structure in the normal display region, so that the fan-out region and the normal display region can have the same or substantially the same distribution density of the light-shielding structure. That is, the problem of mura of the display panel when the screen is off can be improved.

As shown in FIGS. 8, 9 and 12, a first interconnection portion Cnt1 may include a first via contact portion TH1, and the first via contact portion TH1 is connected to a second dummy line Dm2 through a via hole. A recessed structure may appear at a connection part between the second dummy line Dm2 and the first via contact portion TH1, and the recessed structure may change the reflective property of the second dummy line Dm2, thereby causing a second dummy line in a region where no first interconnection portion is provided, a second data fan-out line, and a second dummy line in a region where a first interconnection portion is provided to have different reflective properties, thereby causing the mura on the display panel when the screen is off.

As shown in FIGS. 8, 9, and 12, in this example embodiment, the conductive layer where the first signal lines is located may further include: a second dummy via contact portion DTH2. The second dummy via contact portion DTH2 is located in the normal display region. Among the intersection points of the orthographic projections of the first dummy lines Dm1 and the second dummy lines Dm2 on the base substrate, an intersection point, that is not arranged in correspondence with a first interconnection portion Cnt1, is arranged in correspondence with a second dummy via contact portion DTH2. The second dummy via contact portion DTH2 is insulated from the first dummy line Dm1. A second dummy line Dm2 is connected, through a via hole, to a second dummy via contact portion DTH2 which corresponds to the second dummy line Dm2. A second dummy line Dm2 forming an intersection point is arranged in correspondence with a second dummy via contact portion DTH2 which corresponds to the intersection point. This arrangement can make the reflective properties of respective second dummy lines in the normal display region consistent, thereby improving the mura on the display panel when the screen is off.

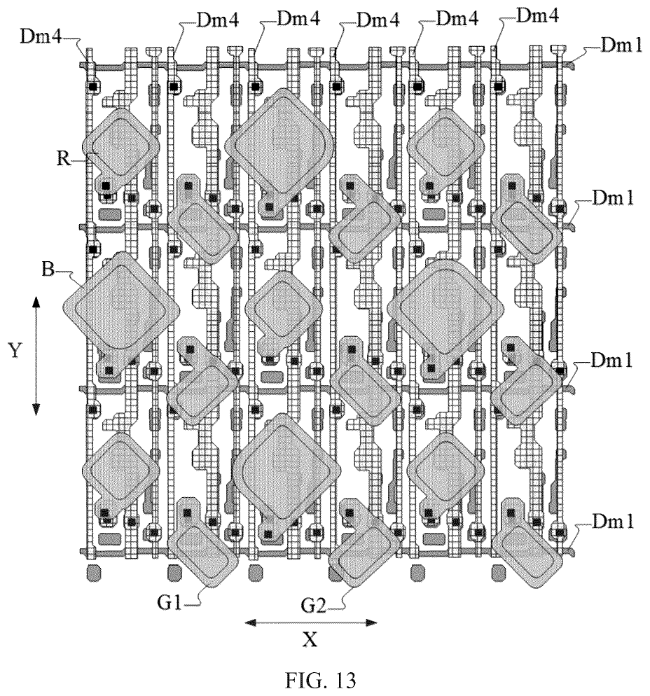

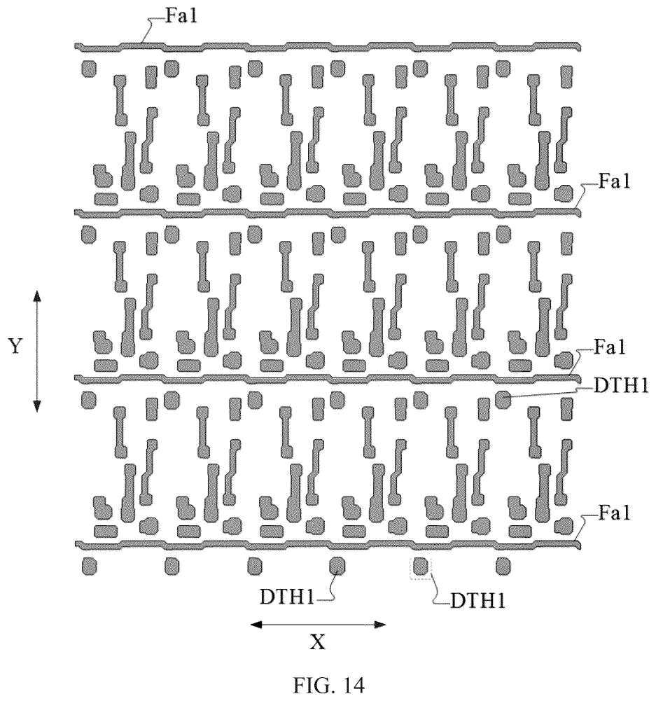

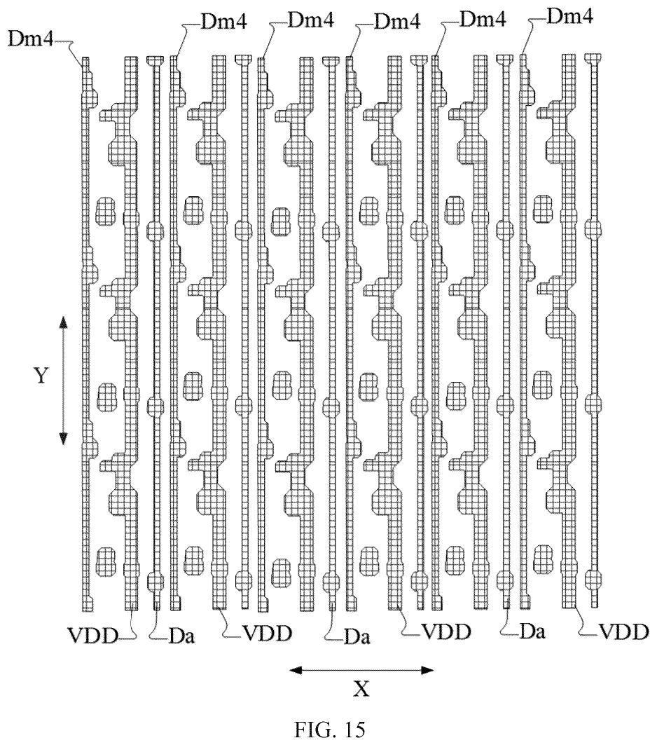

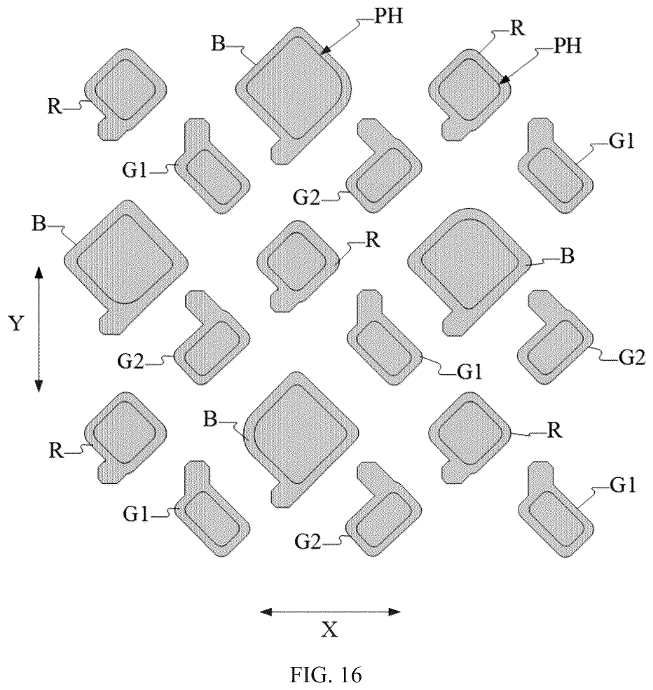

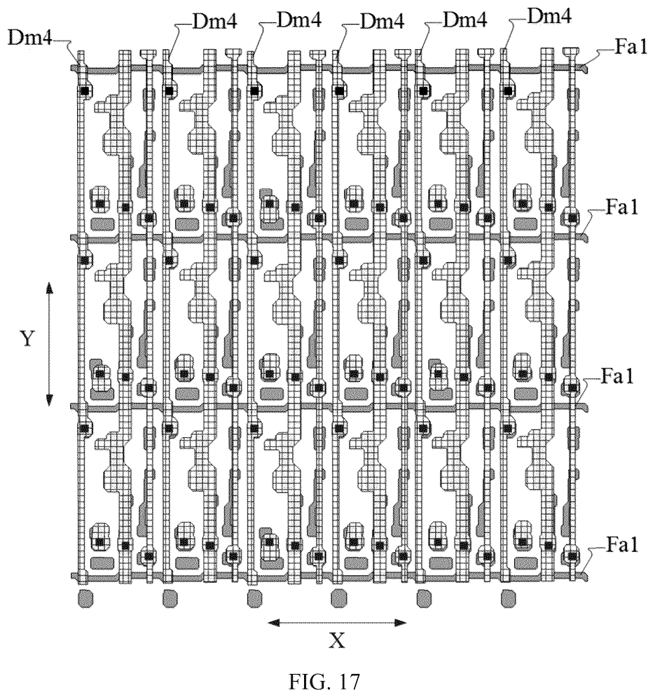

FIG. 13 is a structural layout diagram of a partial region K1 of the fan-out region in FIG. 7. FIG. 14 is a structural layout diagram of the first source-drain layer in FIG. 13. FIG. 15 is a structural layout diagram of the second source-drain layer in FIG. 13. FIG. 16 is a structural layout diagram of the pixel electrode layer and the pixel definition layer in FIG. 13. FIG. 17 is a structural layout diagram of the first source-drain layer and the second source-drain layer in FIG. 13.

As shown in FIG. 7, a part of the first signal lines L1 located in the fan-out region FT forms(form) third dummy line(s) Dm3, and a part of the second signal lines L2 located in the fan-out region FT forms(form) fourth dummy line(s) Dm4. A first dummy line Dm1 is connected to a third dummy line Dm3, and a second dummy line Dm2 is connected to a fourth dummy line Dm4.

In this example embodiment, the conductive layer where the first signal lines L1 are located may further include: a first dummy via contact portion DTH1. The first dummy via contact portion DTH1 is located in the fan-out region FT. An intersection point of orthographic projections of a first signal line L1 (first data fan-out line Fa1) and a second signal line L2 (fourth dummy line Dm4) located in the fan-out region FT on the base substrate is arranged in correspondence with a first dummy via contact portion DTH1. The first dummy via contact portion DTH1 is insulated from the first signal line L1, the second signal line L2 is connected, through a via hole, to the first dummy via contact portion DTH1 corresponding to the second signal line L2, and the second signal line L2 forming the intersection points corresponds to the first dummy via contact portion DTH1 which corresponds to the intersection points. This arrangement can make the reflective properties of the second signal lines in the normal display region and the second signal lines in the fan-out region FT consistent, thereby improving the mura on the display panel when the screen is off.

It should be understood that, in the partial region K2 of the fan-out region FT of the display panel shown in FIG. 7, the intersection point of the orthographic projections of the first signal line L1 (third dummy line) and the second signal line L2 (second data fan-out line) in the fan-out region FT on the base substrate may also be provided in correspondence with a first dummy via contact portion DTH1. The second signal line L2 is connected, through a via hole, to the first dummy via contact portion DTH1 which corresponds to the second signal line L2.

In this example embodiment, a first dummy via contact portion DTH1, a second dummy via contact portion DTH2, and a first via contact portion TH1 form a via contact portion. The minimum distance between the orthographic projections of adjacent via contact portions on the base substrate in the first direction X is S1, and the maximum distance between the orthographic projections of adjacent via contact portions on the base substrate in the first direction X is S2, wherein (S2−S1)/S1 is greater than or equal to 0 and smaller than or equal to 0.2. For example, (S2−S1)/S1 may be equal to 0, 0.1, 0.2, etc. The minimum distance between the orthographic projections of adjacent via contact portions on the base substrate in the second direction Y is S3, and the maximum distance between the orthographic projections of adjacent via contact portions on the base substrate in the second direction Y is S4, wherein (S4−S3)/S3 is greater than or equal to 0 and smaller than or equal to 0.2, where (S4−S3)/S3 may be equal to 0, 0.1, 0.2, etc. This arrangement can make the via contact portions evenly distributed, thereby further improving the problem of mura on the display panel when the screen is off.

In an example embodiment, the minimum distance between the orthogonal projections of two adjacent first signal lines LI on the base substrate in the second direction Y is S5, and the maximum distance between the orthogonal projections of two adjacent first signal lines L1 on the base substrate in the second direction Y is S6, where (S6−S5)/S5 is greater than or equal to 0 and smaller than or equal to 0.2. For example, (S6−S5)/S5 may be equal to 0, 0.1, 0.2, etc. The minimum distance between the orthogonal projections of two adjacent second signal lines L2 on the base substrate in the first direction X is S7, and the maximum distance between the orthogonal projections of two adjacent second signal lines L2 on the base substrate in the first direction X is S8, where (S8−S7)/S7 is greater than or equal to 0 and smaller than or equal to 0.2. For example, (S8−S7)/S7 may be equal to 0, 0.1, 0.2, etc. This arrangement can make the first signal lines L1 and the second signal lines L2 evenly distributed, thereby further improving the problem of mura on the display panel when the screen is.

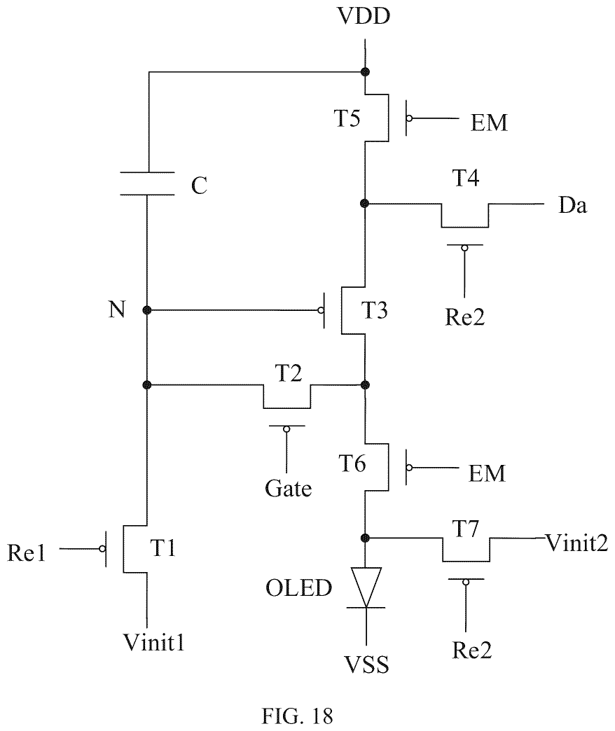

In an example embodiment, the display panel may include a pixel driving circuit, as shown in FIG. 18. FIG. 18 is a schematic structural diagram of a pixel driving circuit in a display panel according to an example embodiment of the present disclosure. The pixel driving circuit may include: a driving transistor T3, a first transistor T1, a second transistor T2, a fourth transistor T4, a fifth transistor T5, a sixth transistor T6, a seventh transistor T7, and a capacitor C. A first electrode of the fourth transistor T4 is connected to a data signal terminal Da, a second electrode of the fourth transistor T4 is connected to a first electrode of the driving transistor T3, and a gate of the fourth transistor T4 is connected to a second reset signal terminal Re2. A first electrode of the fifth transistor T5 is connected to a first power supply terminal VDD, a second electrode of the fifth transistor T5 is connected to a first electrode of the driving transistor T3, and a gate of the fifth transistor T5 is connected to an enable signal terminal EM. A gate of the driving transistor T3 is connected to a node N. A first electrode of the second transistor T2 is connected to the node N, a second electrode of the second transistor T2 is connected to a second electrode of the driving transistor T3, and a gate of the second transistor T2 is connected to a gate driving signal terminal Gate. A first electrode of the sixth transistor T6 is connected to the second electrode of the driving transistor T3, a second electrode of the sixth transistor T6 is connected to a second electrode of the seventh transistor T7, a gate of the sixth transistor T6 is connected to the enable signal terminal EM, a first electrode of the seventh transistor T7 is connected to a second initialization signal terminal Vinit2, and a gate of the seventh transistor T7 is connected to a second reset signal terminal Re2. A second electrode of the first transistor T1 is connected to the node N, a first electrode of the first transistor T1 is connected to a first initialization signal terminal Vinit1, and a gate of the first transistor T1 is connected to a first reset signal terminal Re1. A first electrode of the capacitor C is connected to the node N, and a second electrode of the capacitor C is connected to the first power supply terminal VDD. The pixel driving circuit may be connected to a light-emitting unit OLED, and the pixel driving circuit is used to drive the light-emitting unit OLED to emit light. A first electrode of the light-emitting unit OLED may be connected to the second electrode of the sixth transistor T6, and a second electrode of the light-emitting unit may be connected to a second power supply terminal VSS. The first electrode of the light-emitting unit may be an anode of the light-emitting unit, and the second electrode of the light-emitting unit may be a cathode of the light-emitting unit. The first transistor T1, the second transistor T2, the driving transistor T3, the fourth transistor T4, the fifth transistor T5, the sixth transistor T6, and the seventh transistor T7 may be P-type transistors. P-type transistors have relatively high carrier mobility, which is conducive to realizing a display panel with high resolution, high response speed, high pixel density, and high aperture ratio. The first initialization signal terminal and the second initialization signal terminal may output the same or different voltage signals according to actual conditions.

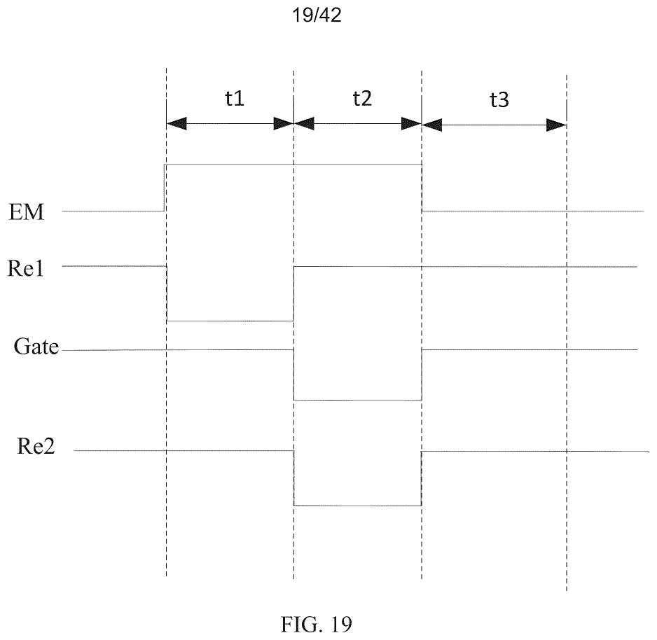

As shown in FIG. 19, it is a timing diagram of the signals on respective nodes in a driving method of the pixel circuit shown in FIG. 18. In this figure, Gate represents the timing diagram of the signal on the gate driving signal terminal Gate, Re1 represents the timing diagram of the signal on the first reset signal terminal Re1, Re2 represents the timing diagram of the signal on the second reset signal terminal Re2, and EM represents the timing diagram of the signal on the enable signal terminal EM. The driving method of the pixel circuit may include a reset stage t1, a compensation stage t2, and a light-emitting stage t3. In the reset stage t1: the first reset signal terminal Re1 outputs a low-level signal, the first transistor T1 is turned on, and the first initialization signal terminal Vinit1 inputs the first initialization signal to the node N. In the compensation stage t2: the second reset signal terminal Re2 and the gate driving signal terminal Gate output low-level signals, the fourth transistor T4, the second transistor T2, and the seventh transistor T7 are turned on, and at the same time the data signal terminal Da outputs a data signal to write a voltage Vdata+Vth to the node N, where Vdata is the voltage of the data signal, and Vth is the threshold voltage of the driving transistor T3, and the second initialization signal terminal Vini2 inputs a second initialization signal to the second electrode of the sixth transistor T6. In the light-emitting stage t3: the enable signal terminal EM outputs a low-level signal, the sixth transistor T6 and the fifth transistor T5 are turned on, and the driving transistor T3 drives the light-emitting unit to emit light under the voltage Vdata+Vth of the node N. The output current formula of the driving transistor is: I=(μWCox/2L)(Vgs−Vth)², where u is the carrier mobility, Cox is the gate capacitance per unit area, W is the width of the channel of the driving transistor, L is the length of the channel of the driving transistor, Vgs is the gate-source voltage difference of the driving transistor, and Vth is the threshold voltage of the driving transistor. The output current I of the driving transistor in the pixel circuit of the present disclosure is I=(μWCox/2L)(Vdata+Vth−Vdd−Vth)². The pixel circuit can avoid the influence of the threshold of the driving transistor on its output current.

In an example embodiment, as shown in FIG. 7, the first dummy lines Dm1 and the second dummy lines Dm2 may be connected to a common electrode layer of the display panel, and the common electrode layer may form the second electrode of the light-emitting unit. It should be understood that in other example embodiments, the first dummy lines and the second dummy lines may also transmit other signals. For example, the first dummy lines and the second dummy lines may also be used to provide a first power supply terminal, a first initialization signal terminal, a second initialization signal terminal, etc.

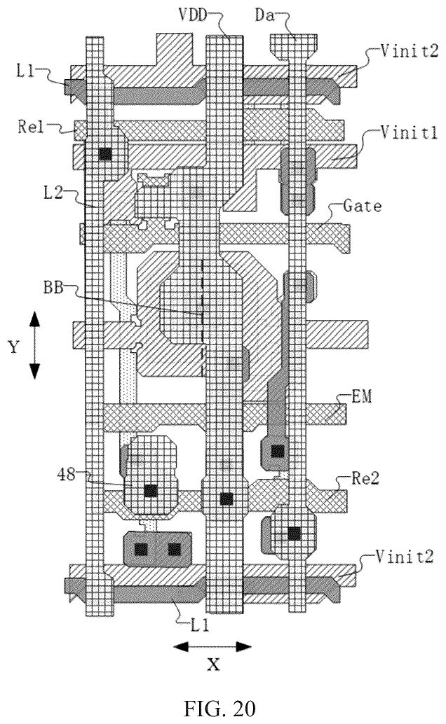

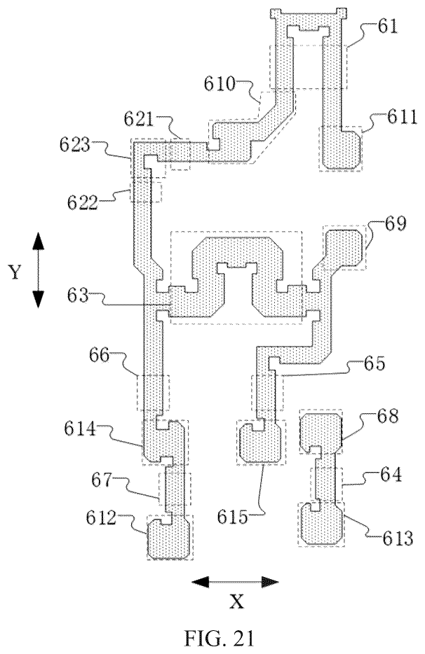

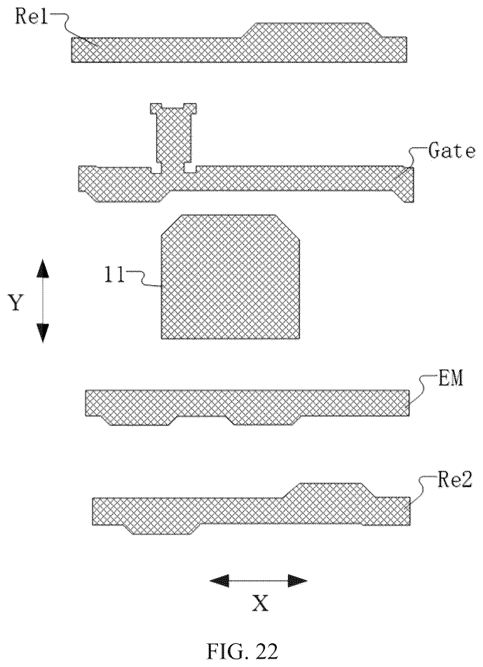

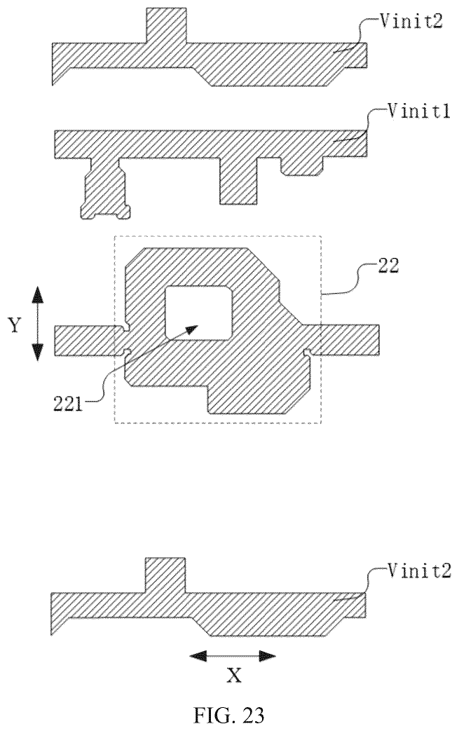

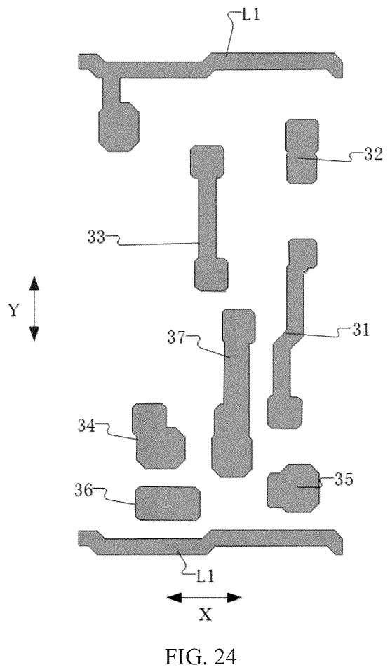

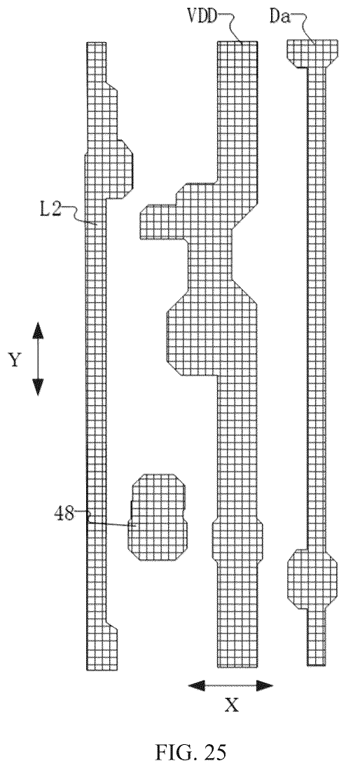

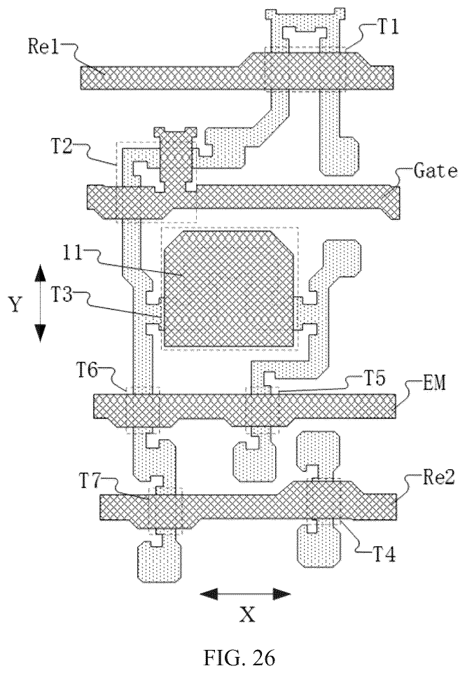

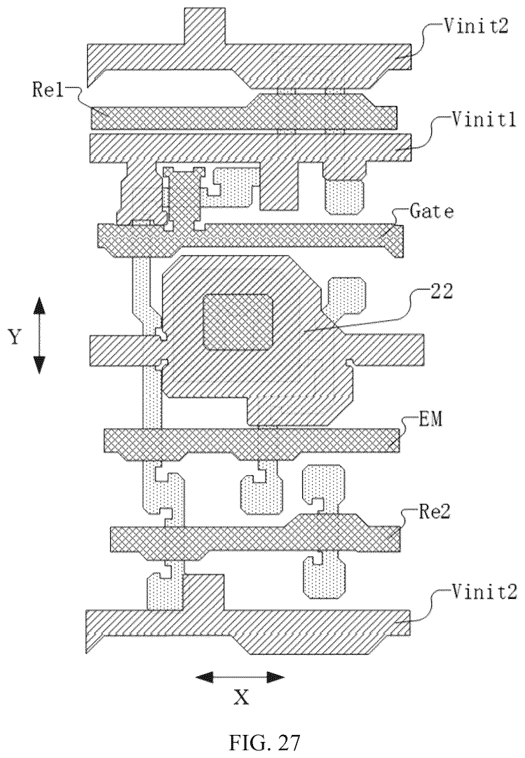

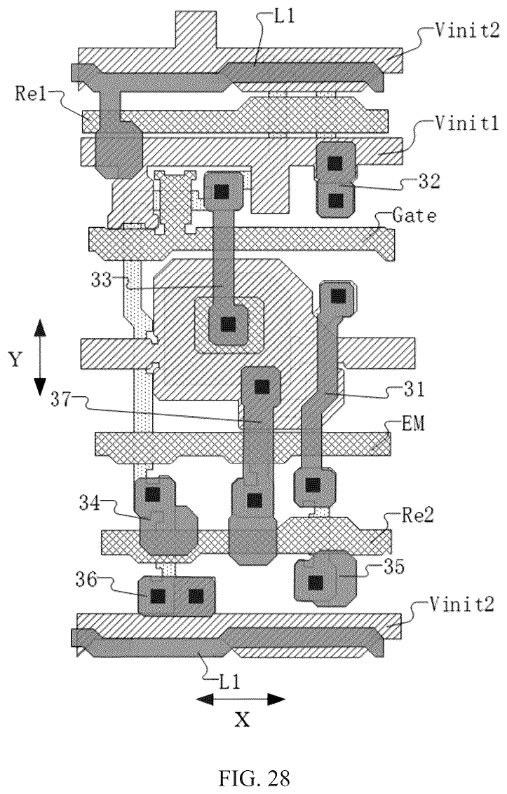

In an example embodiment, the display panel may include the pixel driving circuit shown in FIG. 18. The display panel may further include a base substrate, an active layer, a first gate layer, a second gate layer, a first source-drain layer, and a second source-drain layer stacked in sequence. An insulation layer may be provided between layers in the layered structure. As shown in FIGS. 20 to 28, FIG. 20 is a structural layout diagram of a display panel according to an example embodiment of the present disclosure. FIG. 21 is a structural layout diagram of an active layer in FIG. 20. FIG. 22 is a structural layout diagram of a first gate layer in FIG. 20. FIG. 23 is a structural layout diagram of a second gate layer in FIG. 20. FIG. 24 is a structural layout diagram of a first source-drain layer in FIG. 20. FIG. 25 is a structural layout diagram of a second source-drain layer in FIG. 20. FIG. 26 is a structural layout diagram of the active layer and the first gate layer in FIG. 20. FIG. 27 is a structural layout diagram of the active layer and the first gate layer and the second gate layer in FIG. 20. FIG. 28 is a structural layout diagram of the active layer and the first gate layer, the second gate layer, and the first source-drain layer in FIG. 20.

As shown in FIGS. 20, 21 and 26, the active layer may include: a first active portion 61, a third active portion 63, a fourth active portion 64, a fifth active portion 65, a sixth active portion 66, a seventh active portion 67, a first active sub-portion 621, a second active sub-portion 622, a third active sub-portion 623, an eighth active portion 68, a ninth active portion 69, a tenth active portion 610, an eleventh active portion 611, a twelfth active portion 612, a thirteenth active portion 613, a fourteenth active portion 614 and a fifteenth active portion 615. The first active portion 61 is used to form a channel region of the first transistor T1. The first active sub-portion 621 and the second active sub-portion 622 are used to form a channel region of the second transistor T2. The third active sub-portion 623 is connected between the first active sub-portion 621 and the second active sub-portion 622. The third active portion 63 is used to form a channel region of the driving transistor DT. The fourth active portion 64 is used to form a channel region of the fourth transistor T4. The fifth active portion 65 is used to form a channel region of the fifth transistor T5. The sixth active portion 66 is used to form a channel region of the sixth transistor T6. The seventh active portion 67 is used to form a channel region of the seventh transistor T7. The eighth active portion 68 and the thirteenth active portion 613 are connected to both ends of the fourth active portion 64. The ninth active portion 69 is connected between the third active portion 63 and the fifth active portion 65. The tenth active portion 610 is connected between the first active portion 61 and the first active sub-portion 621. The eleventh active portion 611 is connected to an end of the first active portion 61 away from the first active portion 61. The twelfth active portion 612 is connected to an end of the seventh active portion 67 away from the sixth active portion 66. The fourteenth active portion 614 is connected between the seventh active portion 67 and the sixth active portion 66. The fifteenth active portion 615 is connected to an end of the fifth active portion 65 away from the third active portion 63. The active layer may be formed of a polysilicon material, and accordingly, the first transistor T1, the second transistor T2, the driving transistor T3, the fourth transistor T4, the fifth transistor T5, the sixth transistor T6, and the seventh transistor T7 may be P-type low-temperature polysilicon thin film transistors.

As shown in FIGS. 20, 22, and 26, the first gate layer may include a first reset signal line Re1, a second reset signal line Re2, a gate line Gate, an enable signal line EM, and a first conductive portion 11. The orthographic projections of the first reset signal line Re1, the second reset signal line Re2, the gate line Gate, and the enable signal line EM on the base substrate may all extend along the first direction X. The first reset signal line Re1 is used to provide a first reset signal terminal. The second reset signal line Re2 is used to provide a second reset signal terminal. The gate line Gate is used to provide a gate driving signal terminal. The enable signal line EM is used to provide an enable signal terminal. The orthographic projection of the first reset signal line Re1 on the base substrate covers the orthographic projection of the first active portion 61 on the base substrate, and a partial structure of the first reset signal line Re1 is used to form the gate of the first transistor T1. The orthographic projection of the second reset signal line Re2 on the base substrate covers the orthographic projections of the seventh active portion 67 and the fourth active portion 64 on the base substrate, and a partial structure of the second reset signal line Re2 is used to form the gate of the seventh transistor T7, and a partial structure of the second reset signal line Re2 is used to form the gate of the fourth transistor T4. The orthographic projection of the gate line Gate on the base substrate covers the orthographic projections of the first active sub-portion 621 and the second active sub-portion 622 on the base substrate, and a partial structure of the gate line Gate is used to form the gate of the second transistor T2. The orthographic projection of the enable signal line EM on the base substrate covers the orthographic projections of the fifth active portion 65 and the sixth active portion 66 on the base substrate, and a partial structure of the enable signal line EM is used to form the gate of the fifth transistor T5, and a partial structure of the enable signal line EM is used to form the gate of the sixth transistor T6. The orthographic projection of the first conductive portion 11 on the base substrate covers the orthographic projection of the third active portion 63 on the base substrate, and the first conductive portion 11 is used to form the gate of the driving transistor T3. The first conductive portion 11 may also be reused as the first electrode of the capacitor. In an example embodiment, the orthographic projection of a certain structure on the base substrate extending in a certain direction can be understood as: the orthographic projection of the structure on the base substrate extending in a straight line or extending in a bent line along the direction. In addition, in the display panel, the first gate layer may be used as a mask to perform a process on the active layer to make a part of the active layer behave like a conductor, that is, a region in the active layer covered by the first gate layer may form the channel region of the transistor, and a region in the active layer not covered by the first gate layer forms a conductive structure.

As shown in FIGS. 20, 23, and 27, the second gate layer may include a first initialization signal line Vinit1, a second initialization signal line Vinit2, and a second conductive portion 22. The orthographic projection of the first initialization signal line Vinit1 on the base substrate and the orthographic projection of the second initialization signal line Vinit2 on the base substrate may extend along the second direction Y. The first initialization signal line Vinit1 may be used to provide a first initialization signal terminal, and the second initialization signal line Vinit2 may be used to provide a second initialization signal terminal. The orthographic projection of the second conductive portion 22 on the base substrate may overlap with the orthographic projection of the first conductive portion 11 on the base substrate, and the second conductive portion 22 may be used to form a first electrode of the capacitor C.

As shown in FIGS. 20, 24, and 28, the first source-drain layer may include a first bridging portion 31, a second bridging portion 32, a third bridging portion 33, a fourth bridging portion 34, a fifth bridging portion 35, a seventh bridging portion 37, and first signal line(s) L1. The first bridging portion 31 may be connected to the eighth active portion 68 and the ninth active portion 69 through via holes (black squares indicate positions of via holes) to connect the second electrode of the fourth transistor T4 and the first electrode of the driving transistor T3. The second bridging portion 32 may be connected to the eleventh active portion 611 and the first initialization signal line Vinit1 through via holes to connect the first electrode of the first transistor T1 and the first initialization signal terminal. The third bridging portion 33 may be connected to the first conductive portion 11 and the tenth active portion 610 through via holes to connect the second electrode of the first transistor T1, the gate of the driving transistor T3, and the first electrode of the second transistor T2. An opening 221 is formed in the second conductive portion 22, and the orthographic projection of a via hole connected between the third bridging portion 33 and the first conductive portion 11 on the base substrate is located within the orthographic projection of the opening 221 on the base substrate so as to be insulated from the second conductive portion 22. The fourth bridging portion 34 may be connected to the fourteenth active portion 614 through a via hole to connect the second electrode of the sixth transistor T6 and the second electrode of the seventh transistor. The fifth bridging portion 35 may be connected to the thirteenth active portion 613 through a via hole to connect the first electrode of the fourth transistor T4. The sixth bridging portion 36 is connected to the twelfth active portion 612 and the second initialization signal line Vinit2 through via holes respectively to connect the first electrode and the second initialization signal terminal of the seventh transistor. The seventh bridging portion 37 may be connected to the second conductive portion 22 and the fifteenth active portion 615 through via holes respectively to connect the first electrode of the fifth transistor T5 and the second electrode of the capacitor C.

As shown in FIGS. 20 and 25, the second source-drain layer may include a power supply line VDD, a data line Da, a second signal line L2, and an eighth bridging portion 48. The orthographic projections of the power supply line VDD, the second signal line L2, and the data line Da on the base substrate may extend along the second direction Y. The power supply line VDD may be used to provide a first power supply terminal, and the power supply line VDD may be connected to the seventh bridging portion 37 through a via hole to connect the first power supply terminal and the first electrode of the fifth transistor T5 and the second electrode of the capacitor C. The data line Da may be used to provide a data signal terminal, and the data line Da may be connected to the fifth bridging portion 35 through a via hole to connect the data signal terminal and the first electrode of the fourth transistor T4. The eighth bridging portion 48 may be connected to the fourth bridging portion 34 through a via hole to connect the second electrode of the sixth transistor T6 and the second electrode of the seventh transistor T7. The eighth bridging portion 48 may also be connected to an electrode portion through a via hole.

In an example embodiment, as shown in FIGS. 8 and 20, a first dummy line Dm1 is arranged in correspondence with a pixel driving circuit. In the pixel driving circuit and the first dummy line Dm1 which mutually correspond to each other, the orthographic projection of the first dummy line Dm1 on the base substrate is located at a side of the orthographic projection of the first conductive portion 11 on the base substrate away from the orthographic projection of the gate line Gate on the base substrate. The second dummy line Dm2 is arranged in correspondence with the pixel driving circuit. In the pixel driving circuit and the second dummy line Dm2 which mutually correspond to each other, the orthographic projection of the second dummy line Dm2 on the base substrate is located at a side of the orthographic projection of the power supply line VDD on the base substrate away from the orthographic projection of the data line Da on the base substrate. A first interconnection portion Cnt1 is arranged in correspondence with a first dummy line Dm1 and a second dummy line Dm2 which are directly connected to the first interconnection portion Cnt1, and a pixel driving circuit and the first interconnection portion Cnt1 corresponding to the same group of the first dummy line Dm1 and the second dummy line Dm2 are correspondingly arranged.

In an example embodiment, as shown in FIGS. 8 and 13, the plurality of electrode portions include a first electrode portion R, a second electrode portion G1, a third electrode portion B, and a fourth electrode portion G2. The first electrode portion R may be used to form a first electrode of a red light-emitting unit. The second electrode portion G1 and the fourth electrode portion G2 may be used to form first electrodes of green light-emitting units. The third electrode portion B may be used to form a first electrode of a blue light-emitting unit. Among multiple electrode portions connected to pixel driving circuits in the same row, the first electrode portion R, the second electrode portion G1, the third electrode portion B, and the fourth electrode portion G2 are alternately distributed in sequence in the row direction. In two adjacent columns of pixel driving circuits, the first electrode portion R and the third electrode portion B are connected to pixel driving circuits in the same column, and the first electrode portion R and the third electrode portion B connected to the pixel driving circuits in the same column are alternately distributed in sequence in the column direction. The second electrode portion G1 and the fourth electrode portion G2 are connected to the pixel driving circuits in another column, and the second electrode portion G1 and the fourth electrode portion G2 connected to the pixel driving circuit in the same column are alternately distributed in sequence in the column direction. In four adjacent pixel driving circuits in the first direction, a pixel driving circuit corresponding to the first electrode portion R is correspondingly provided with a first interconnection portion, a pixel driving circuit corresponding to the second electrode portion G1 is correspondingly provided with a first interconnection portion, and a pixel driving circuit corresponding to the third electrode portion B is correspondingly provided with a first interconnection portion. The fourth electrode portion G2 is not correspondingly provided with a first interconnection portion.

It should be understood that in other example embodiments, in the normal display region, n pixel driving circuits which are adjacent in the first direction are correspondingly provided with m first interconnection portions, wherein n is a positive integer greater than or equal to 2, m is a positive integer greater than or equal to 1, and n is greater than m.

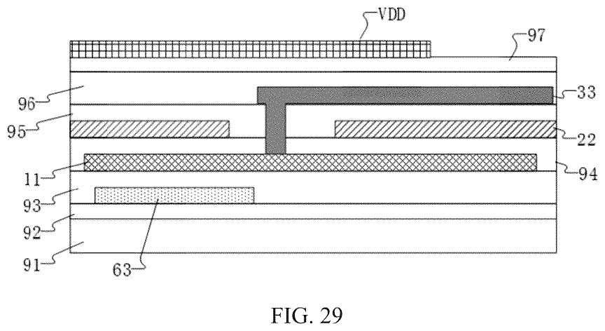

As shown in FIG. 29, it is a partial cross-sectional view of the display panel shown in FIG. 20 cut along the dotted line BB. The display panel may further include a buffer layer 92, a first insulation layer 93, a second insulation layer 94, a first dielectric layer 95, a passivation layer 96, and a planarization layer 97. The base substrate 91, the buffer layer 92, the active layer, the first insulation layer 93, the first gate layer, the second insulation layer 94, the second gate layer, the first dielectric layer 95, the first source-drain layer, the passivation layer 96, the planarization layer 97, and the second source-drain layer are stacked in sequence. The first insulation layer 93 and the second insulation layer 94 may be silicon oxide layers, the first dielectric layer 95 may be a silicon nitride layer, the passivation layer 96 and the buffer layer 92 may be made of silicon oxide, silicon nitride, etc., and the material of the planarization layer 97 may be an organic material, such as polyimide (PI), polyethylene terephthalate (PET), polyethylene naphthalate (PEN), silicon-glass bonding structure (SOG, silicon on glass), and the like. The base substrate 91 may include a glass substrate, a blocking layer, and a polyimide layer stacked in sequence, and the blocking layer may be an inorganic material. The material of the first gate layer and the second gate layer may be one of molybdenum, aluminum, copper, titanium, niobium or an alloy, or a molybdenum/titanium alloy or laminated molybdenum/titanium, etc. The material of the first source-drain layer and the second source-drain layer may include a metal material, for example, the metal material may be one of molybdenum, aluminum, copper, titanium, niobium or an alloy, or a molybdenum/titanium alloy or laminated molybdenum/titanium, etc., or laminated titanium/aluminum/titanium. The square resistance of any conductive layer in the first gate layer and the second gate layer may be greater than the square resistance of any conductive layer in the first source-drain layer and the second source-drain layer.

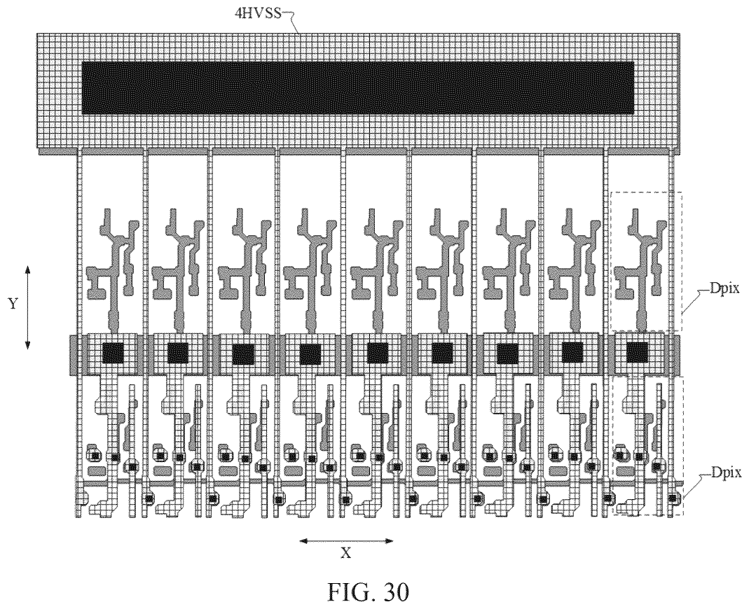

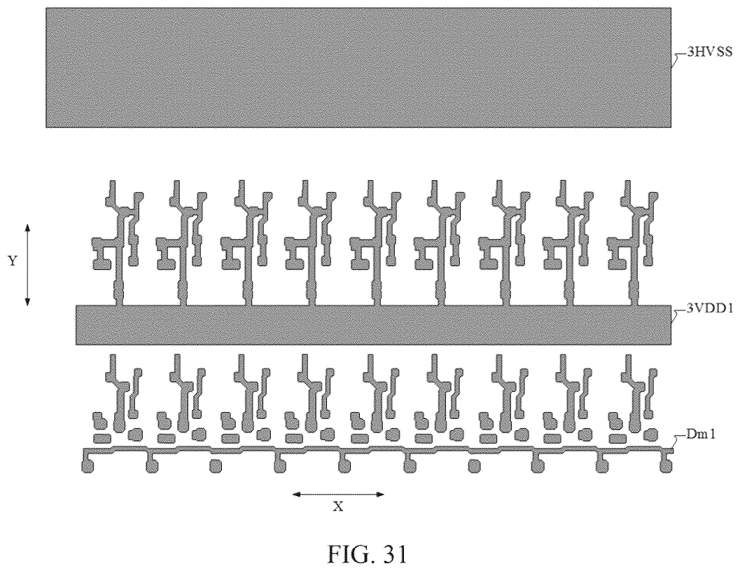

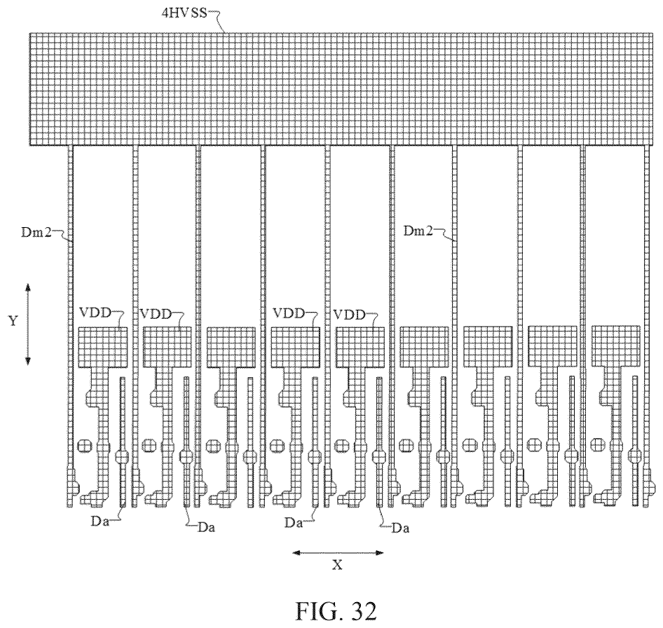

As shown in FIGS. 30 to 32, FIG. 30 is a partial layout structure of a region K3 in FIG. 7, FIG. 31 is a structural layout diagram of the first source-drain layer in FIG. 30, and FIG. 32 is a structural layout diagram of the second source-drain layer in FIG. 30.

As shown in FIG. 7, the display panel further includes a frame region CC located around the display region AA. The frame region CC may include a first frame region (left frame) and a second frame region (right frame) arranged oppositely in the first direction, and a third frame region (upper frame) and a fourth frame region (lower frame) arranged oppositely in the second direction. As shown in FIGS. 30 to 32, the display panel may include an electrode ring 4HVSS located in the frame region, and the electrode ring 4HVSS may be connected to the common electrode layer through a via hole. The electrode ring 4HVSS may be located in the second source-drain layer. In the upper frame of the display panel, the second dummy line Dm2 may be connected to the electrode ring 4HVSS located in the upper frame.

As shown in FIGS. 30 to 32, the first source-drain layer may further include a first electrode line 3HVSS located in the upper frame, the orthographic projection of the first electrode line 3HVSS on the base substrate extends along the first direction X, the electrode ring 4HVSS may be connected to the first electrode line 3HVSS through a via hole (black rectangular block). The first electrode line 3HVSS can reduce the resistance of the electrode ring 4HVSS, thereby reducing the voltage difference between different positions of the electrode ring 4HVSS.

As shown in FIGS. 30 to 32, the display panel may further include a dummy pixel driving circuit Dpix located in the upper frame, and a sub-pixel unit where the dummy pixel driving circuit Dpix is located does not emit light. FIG. 30 only shows a partial structure of two rows of dummy pixel driving circuits Dpix. The first source-drain layer may further include a second electrode line 3VDD1, the orthographic projection of the second electrode line 3VDD1 on the base substrate may extend along the first direction, and the second electrode line 3VDD1 may be connected to a power supply line VDD in the display region.

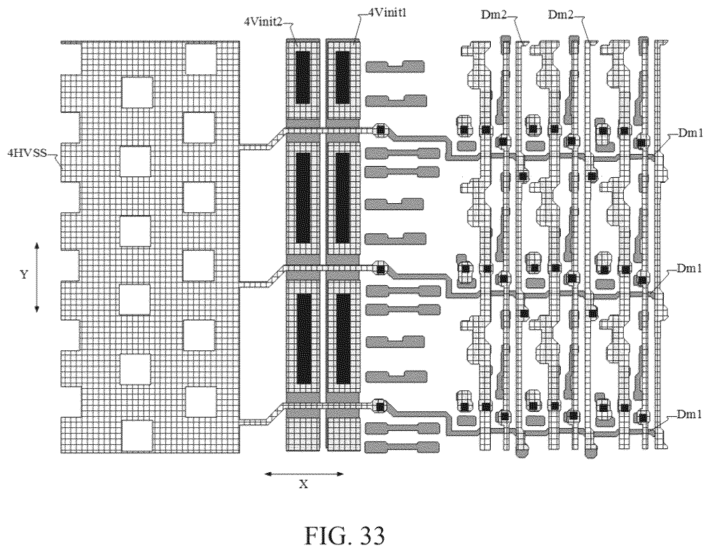

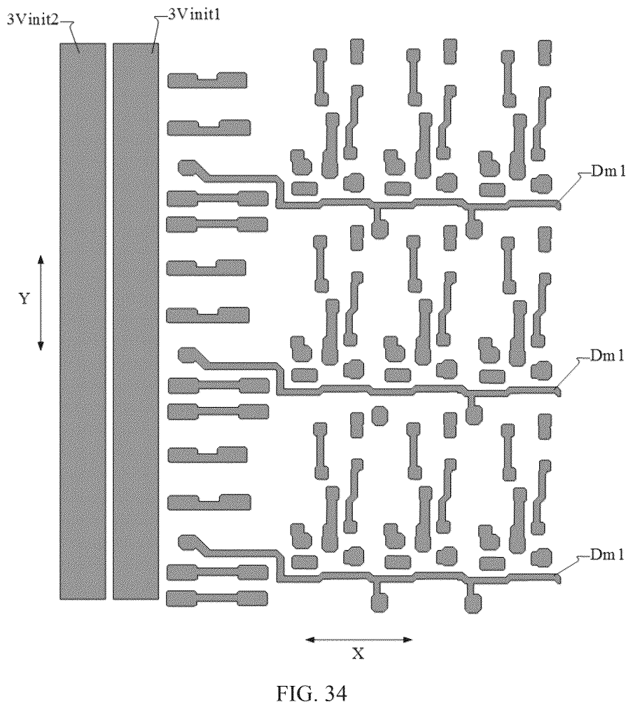

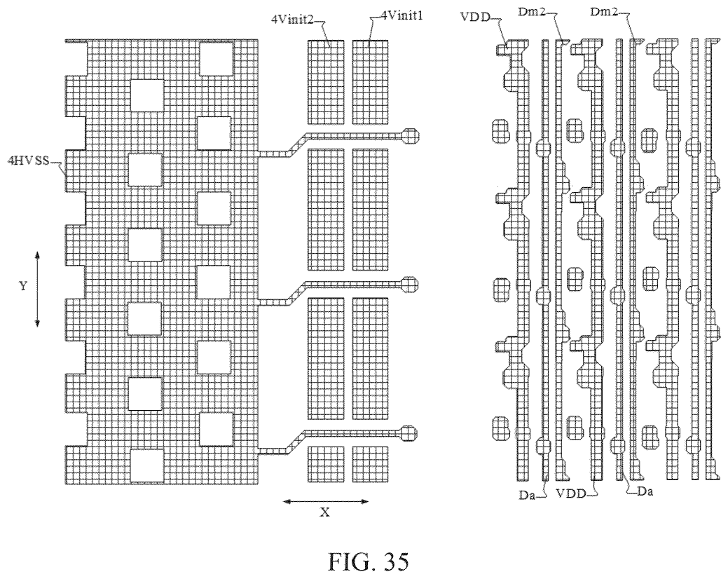

As shown in FIGS. 33 to 35, FIG. 33 is a partial layout structure of a region K4 in FIG. 7, FIG. 34 is a structural layout diagram of the first source-drain layer in FIG. 33, and FIG. 35 is a structural layout diagram of the second source-drain layer in FIG. 33.

The electrode ring 4HVSS located in the left frame may be connected to a first dummy line Dm1 through a via hole. Similarly, the electrode ring 4HVSS located in the right frame may also be connected to a first dummy line Dm1 through a via hole.

The first source-drain layer may further include: a first initialization connection line 3Vinit1 and a second initialization connection line 3Vinit2. The orthographic projections of the first initialization connection line 3Vinit1 and the second initialization connection line 3Vinit2 on the base substrate may extend along the second direction Y. The first initialization connection 3Vinit1 may be connected to a first initialization signal line Vinit1 located in the display region, and the second initialization connection line 3Vinit2 may be connected to a second initialization signal line Vinit2 located in the display region.

The second source-drain layer may further include a first initialization conductive portion 4Vinit1 and a second initialization conductive portion 4Vinit2. The first initialization conductive portion 4Vinit1 may be connected to the first initialization connection line 3Vinit1 through a via hole to reduce the resistance of the first initialization connection line 3Vinit1. The second initialization conductive portion 4Vinit2 may be connected to the second initialization connection line 3Vinit2 through a via hole to reduce the resistance of the second initialization connection line 3Vinit2.

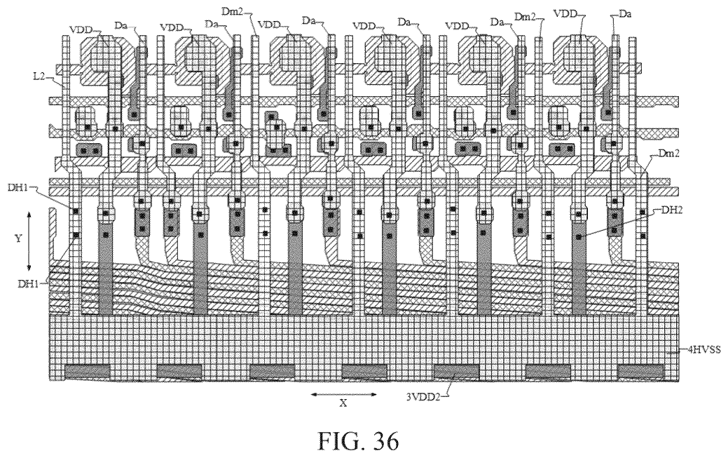

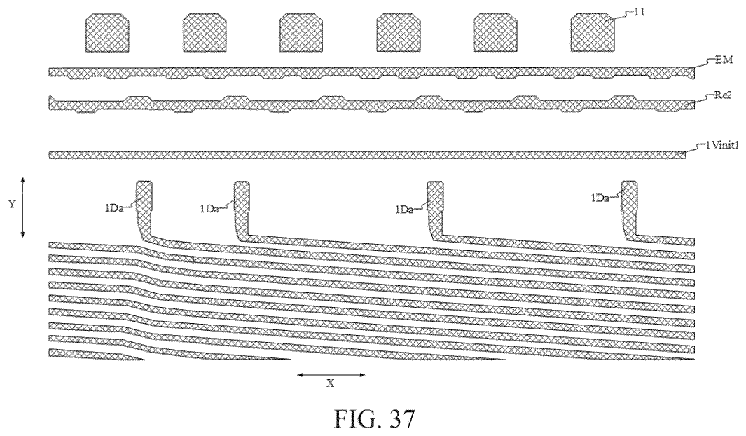

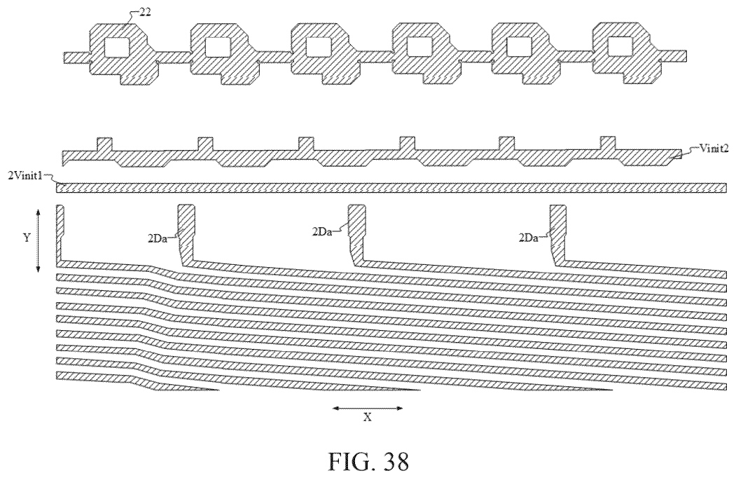

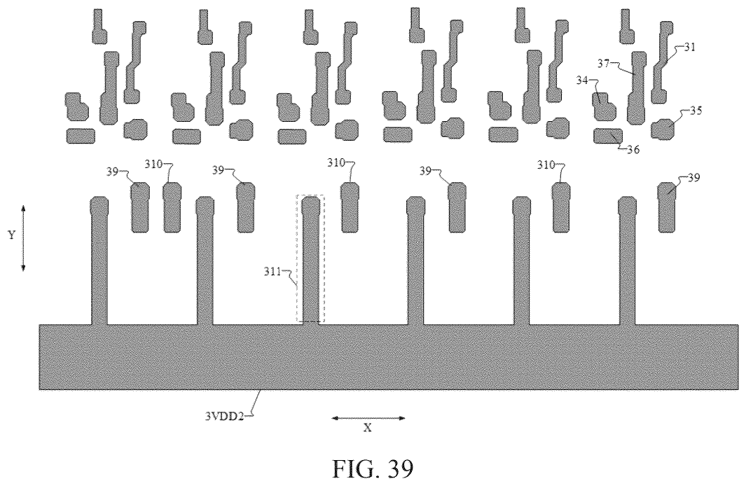

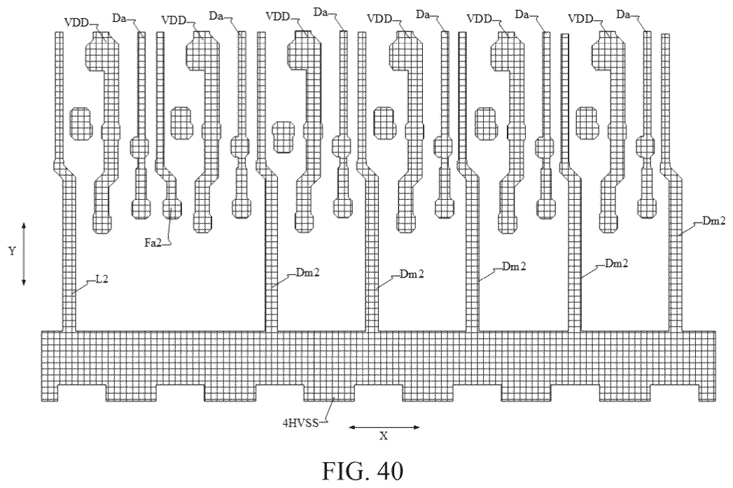

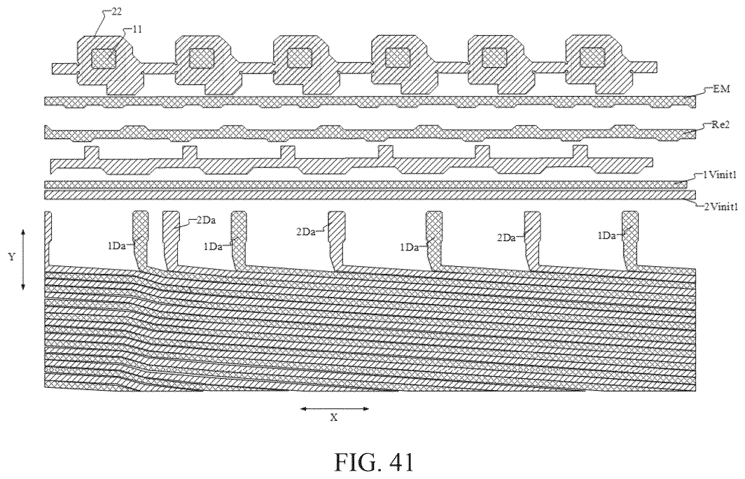

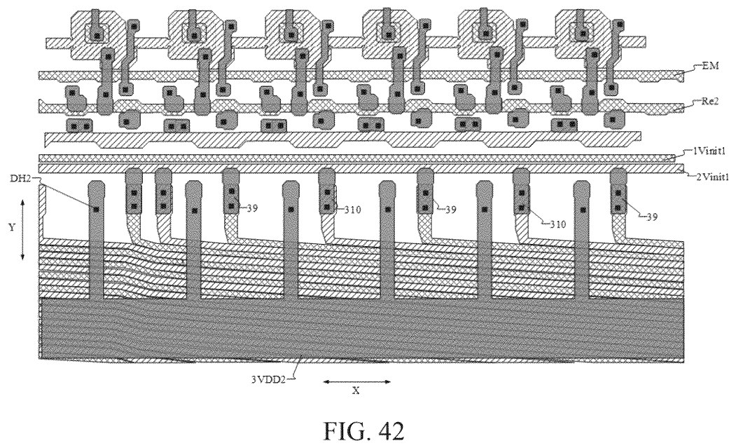

As shown in FIGS. 36 to 42, FIG. 36 is a partial layout structure of a region K5 in FIG. 7. FIG. 37 is a structural layout diagram of a first gate layer in FIG. 36. FIG. 38 is a structural layout diagram of a second gate layer in FIG. 36. FIG. 39 is a structural layout diagram of a first source-drain layer in FIG. 36. FIG. 40 is a structural layout diagram of a second source-drain layer in FIG. 36. FIG. 41 is a structural layout diagram of the first gate layer and the second gate layer in FIG. 36. FIG. 42 is a structural layout diagram of the first gate layer, the second gate layer, and the first source-drain layer in FIG. 36.

As shown in FIGS. 36 to 42, the first gate layer may further include a first data lead line 1Da. The second gate layer may further include a second data lead line 2Da. The orthographic projection of the first data lead line 1Da on the base substrate and the orthographic projection of the second data lead line 2Da on the base substrate may be arranged alternately in sequence. A data line Da and a second data fan-out line Fa2 in the display region may be connected to the first data lead line 1Da through the ninth bridging portion 39. The data line Da in the display region may be connected to the second data lead line 2Da through the tenth bridging portion 310.

As shown in FIGS. 36 to 42, the first source-drain layer may further include a power supply connection line 3VDD2. The orthographic projection of the power supply connection line 3VDD2 on the base substrate may extend along the first direction X, and a power supply line VDD in the display region may be connected to the power supply connection line 3VDD2 via the eleventh bridging portion 311.

As shown in FIGS. 36 to 42, a second dummy line Dm2 located in the display region may be connected to the electrode ring 4HVSS located in the lower frame. The power management circuit of the display panel may provide a power supply signal to the electrode ring 4HVSS located in the lower frame.

As shown in FIGS. 36 to 42, the first gate layer may further include a first initialization dummy line 1Vinit1, and the second gate layer may further include a second initialization dummy line 2Vinit1. Both the first initialization dummy line 1Vinit1 and the second initialization dummy line 2Vinit1 may be connected to a first initialization signal line located in the display region. For example, the first initialization dummy line 1Vinit1 and the second initialization dummy line 2Vinit1 may be connected to a first initialization connection line 3Vinit1. The first initialization dummy line 1Vinit1 and the second initialization dummy line 2Vinit1 may allow different regions of the display panel to have a more uniform distribution density of gate lines, thereby improving the display uniformity of the display panel.

As shown in FIGS. 36 to 42, a second dummy line Dm2 may be connected to a first dummy conductive portion (not shown) located in the active layer through a first dummy via hole DH1. The first dummy conductive portion(s) may be arranged in a one-to-one correspondence with the first dummy via hole(s) DH1. The eleventh bridging portion 311 may be connected to a second dummy conductive portion (not shown) located in the active layer through a second dummy via DH2. The second dummy conductive portion(s) may be arranged in a one-to-one correspondence with the second dummy via hole(s) DH2. The first dummy conductive portion(s) and the second dummy conductive portion(s) are arranged independently. The first dummy via hole(s) DH1 and the second dummy via hole(s) DH2 can make different regions of the display panel have a more uniform via hole distribution density, thereby improving the display uniformity of the display panel.

It should be noted that, in the above embodiments, black squares drawn at a side of the second source-drain layer away from the base substrate indicate via holes connecting the second source-drain layer to other layers at a side facing the base substrate; the black squares drawn at a side of the first source-drain layer away from the base substrate indicates via holes connecting the first source-drain layer to other layers at a side facing the base substrate. The black squares only represent the positions of the via holes, and different via holes represented by black squares at different positions may run through different insulation layers.

It should be noted that the scales of the drawings in the present disclosure may be used as a reference in the actual processes, but the present disclosure is not limited to the scales. For example, the width-to-length ratio of a channel, the thickness and spacing of respective film layers, and the widths and spacing of respective signal lines may be adjusted according to actual needs. The number of pixels in the display substrate and the number of sub-pixels in each pixel are not limited to the numbers shown in the drawings. The drawings described in the present disclosure are only structural schematic diagrams. In addition, qualifiers such as first and second are only used to define different structural names, and they do not mean a specific order and quantity. A transistor refers to an element including at least three terminals: a gate, a drain and a source. The transistor has a channel region between the drain (or called the drain electrode terminal, the drain region or the drain electrode) and the source (or called the source electrode terminal, the source region or the source electrode), and current can flow through the drain, the channel region and the source. In an example embodiment, the channel region refers to a region where the current mainly flows. In an example embodiment, the first electrode can be a drain and the second electrode may be a source, or the first electrode may be a source and the second electrode may be a drain. In a case of using a transistor with an opposite polarity or when the current direction changes during circuit operation, the functions of the “source” and the “drain” are sometimes interchanged. Therefore, in an example embodiment, the “source” and the “drain” may be interchanged. In addition, the gate may also be called a control electrode.

An example embodiment also provides a display device. The display device includes the above described display panel. The display device may be a display device such as a mobile phone, a tablet computer, a television, etc.

Those skilled in the art will readily appreciate other embodiments of the present disclosure after considering the specification and practicing what is disclosed herein. The present disclosure is intended to cover any variations, uses, or adaptations of the present disclosure that follow the general principles of the present disclosure and include common knowledge or customary technical means in the art that are not disclosed in the present disclosure. The specification and embodiments are to be considered merely as illustrative, and the true scope and spirit of the present disclosure are indicated by the claims.

It should be understood that the present disclosure is not limited to the exact structures that have been described above and shown in the drawings, and that various modifications and changes may be made without departing from the scope of the present disclosure. The scope of the present disclosure is limited only by the appended claims.

1. A display panel, wherein a display region of the display panel comprises a fan-out region and a normal display region outside the fan-out region, and the display panel further comprises:
a base substrate;
a plurality of data lines located in the display region, wherein orthographic projections of the data lines on the base substrate are spaced apart along a first direction and extend along a second direction, and the first direction intersects the second direction;
a plurality of first signal lines, wherein orthographic projections of the first signal lines on the base substrate extend along the first direction and are spaced apart along the second direction, a part of the first signal lines located in the fan-out region form at least one first data fan-out line, and at least one first signal line located in the normal display region forms at least one first dummy line, one of the at least one first data fan-out line is arranged in correspondence with a corresponding data line in the plurality of data lines, and the one of the at least one first data fan-out line is connected to the corresponding data line which corresponds to the one of the at least one first data fan-out line;
a plurality of second signal lines located in a different conductive layer from the first signal lines, wherein orthographic projections of the second signal lines on the base substrate extend along the second direction and are spaced apart along the first direction, a part of the second signal lines located in the fan-out region forms at least one second data fan-out line, and at least one second signal line located in the normal display region forms at least one second dummy line, one of the at least one second data fan-out line is arranged in correspondence with a corresponding first data fan-out line, and the one of the at least one second data fan-out line is connected to the corresponding first data fan-out line;
a plurality of first interconnection portions located in the normal display region, wherein one of the plurality of first interconnection portions is connected between a first dummy line and a second dummy line, and an orthographic projection of the first dummy line on the base substrate interests an orthographic projection of the second dummy line on the base substrate; and
a pixel electrode layer comprising a plurality of electrode portions, wherein orthographic projections of the electrode portions on the base substrate do not overlap with orthographic projections of the first interconnection portions on the base substrate.

2. The display panel according to claim 1, wherein the plurality of first signal lines and the first interconnection portions are located in a same conductive layer, and the plurality of second signal lines are located in a same conductive layer;
wherein the conductive layer where the second signal lines are located is located at a side of the conductive layer where the first signal lines is located away from the base substrate;
wherein one of the first interconnection portions and one of the at least one first dummy line are connected in a same layer, and the one of the first interconnection portions and one of the at least one second dummy line are connected through a via hole;
wherein an orthographic projection of the one of the at least one second dummy line on the base substrate covers an orthographic projection of the one of the first interconnection portions on the base substrate.

3. The display panel according to claim 2, further comprising:
a first source-drain layer between the base substrate and the pixel electrode layer, wherein the first source-drain layer comprises the first signal lines and the first interconnection portions;
a second source-drain layer between the first source-drain layer and the pixel electrode layer, wherein the second source-drain layer comprises the second signal lines and the data lines.

4. The display panel according to claim 1, wherein the at least one first dummy line comprises a plurality of first dummy lines, and the at least one second dummy line comprises a plurality of second dummy lines;
a part of intersection points of orthographic projections of the first dummy lines and the second dummy lines on the base substrate are arranged in correspondence with the first interconnection portions, and one of the first interconnection portions is connected between a first dummy line and a second dummy line which correspond to the one of the first interconnection portions;
wherein the number of intersection points of the orthographic projections of the first dummy lines on the base substrate and the orthographic projections of the second dummy lines on the base substrate is greater than the number of the first interconnection portions.

5. The display panel according to claim 4, wherein the display panel comprises pixel driving circuits;
wherein in the normal display region, a part of the pixel driving circuits are correspondingly provided with one of the first interconnection portions, and n pixel driving circuits which are adjacent in the first direction are correspondingly provided with m first interconnection portions;
wherein n is a positive integer greater than or equal to 2, m is a positive integer greater than or equal to 1, and n is greater than m.

6. The display panel according to claim 5, wherein n is equal to 4, m is equal to 3, the first direction is a row direction, and the second direction is a column direction;
wherein the plurality of electrode portions comprise a first electrode portion, a second electrode portion, a third electrode portion, and a fourth electrode portion;
wherein among a plurality of electrode portions connected to pixel driving circuits in a same row, the first electrode portion, the second electrode portion, the third electrode portion, and the fourth electrode portion are alternately distributed in sequence in the row direction;
wherein in two adjacent columns of pixel driving circuits, the first electrode portion and the third electrode portion are connected to a same column of pixel driving circuits, and the first electrode portion and the third electrode portion connected to the same column of pixel driving circuits are alternately distributed in sequence in the column direction, the second electrode portion and the fourth electrode portion are connected to another column of pixel driving circuits, and the second electrode portion and the fourth electrode portion connected to a same column of pixel driving circuits are alternately distributed in sequence in the column direction;
wherein among four pixel driving circuits which are adjacent in the first direction, a pixel driving circuit corresponding to the first electrode portion is correspondingly provided with one of the first interconnection portions, a pixel driving circuit corresponding to the second electrode portion is correspondingly provided with another one of the first interconnection portions, and a pixel driving circuit corresponding to the third electrode portion is correspondingly provided with a further one of first interconnection portions.

7. The display panel according to claim 5, wherein one of the pixel driving circuits comprises a driving transistor, a second transistor and a fifth transistor, a first electrode of the second transistor is connected to a gate of the driving transistor, a second electrode of the second transistor is connected to a second electrode of the driving transistor, a first electrode of the fifth transistor is connected to a power supply line, and a second electrode of the fifth transistor is connected to a first electrode of the driving transistor;
wherein the display panel further comprises:
a first gate layer between the base substrate and the pixel electrode layer, wherein the first gate layer comprises a first conductive portion and a gate line, an orthographic projection of the gate line on the base substrate extends along the first direction, the first conductive portion is used to form the gate of the driving transistor, and a partial structure of the gate line is used to form a gate of the second transistor; and
a second source-drain layer between the first gate layer and the pixel electrode layer, wherein the second source-drain layer comprises the power supply line and the data lines, and an orthographic projection of the power supply line on the base substrate and the orthographic projection of the data lines on the base substrate extend along the second direction;
wherein one of the at least one first dummy line is arranged in correspondence with a pixel driving circuit, and in the pixel driving circuit and the one of the at least one first dummy line which mutually correspond to each other, an orthographic projection of the one of the at least one first dummy line on the base substrate is located at a side of an orthographic projection of the first conductive portion on the base substrate away from an orthographic projection of the gate line on the base substrate;
wherein one of the at least one second dummy line is arranged in correspondence with a pixel driving circuit, and in the pixel driving circuit and the one of the at least one second dummy line which mutually correspond to each other, an orthographic projection of the one of the at least one second dummy line on the base substrate is located at a side of the orthographic projection of the power supply line on the base substrate away from an orthographic projection of a corresponding data line on the base substrate;
wherein one of the first interconnection portions is arranged in correspondence with a first dummy line and a second dummy line which are directly connected to the one of the first interconnection portions, and a pixel driving circuit corresponding to a same group of the first dummy line and the second dummy line is arranged in correspondence with the one of the first interconnection portions.

8. The display panel according to claim 4, wherein the conductive layer where the first signal lines are located further comprises:
a first dummy via contact portion located in the fan-out region, an intersection point of orthographic projections of a first signal line and a second signal line located in the fan-out region on the base substrate is arranged in correspondence with the first dummy via contact portion, the first dummy via contact portion is insulated from a corresponding first signal line, and one of the second signal lines is connected, through a via hole, to a first dummy via contact portion corresponding to the one of the second signal lines;
a second dummy via contact portion located in the normal display region, wherein among intersection points of orthographic projections of first dummy lines and second dummy lines on the base substrate, an intersection point which is not arranged in correspondence with a first interconnection portion is arranged in correspondence with the second dummy via contact portion, the second dummy via contact portion is insulated from a corresponding first dummy line, and one of the second dummy lines is connected to, through a via hole, a second dummy via contact portion which corresponds to the one of second dummy lines.

9. The display panel according to claim 8, wherein one of the first interconnection portions comprises a first via contact portion, and the first via contact portion is connected to a second dummy line through a via hole;
wherein the first dummy via contact portion, the second dummy via contact portion, and the first via contact portion form a via contact portion;
wherein the minimum distance between orthographic projections of adjacent via contact portions on the base substrate in the first direction is S1, and the maximum distance between the orthographic projections of adjacent via contact portions on the base substrate in the first direction is S2, wherein (S2−S1)/S1 is greater than or equal to 0 and smaller than or equal to 0.2;
wherein the minimum distance between the orthographic projections of adjacent via contact portions on the base substrate in the second direction is S3, and the maximum distance between the orthographic projections of adjacent via contact portions on the base substrate in the second direction is S4, wherein (S4−S3)/S3 is greater than or equal to 0 and smaller than or equal to 0.2.

10. The display panel according to claim 8, wherein an orthographic projection of the first dummy via contact portion on the base substrate at least partially overlaps with an orthographic projection of one of the electrode portions on the base substrate;
wherein an orthographic projection of the second dummy via contact portion on the base substrate at least partially overlaps with the orthographic projection of the one of the electrode portions on the base substrate.

11. The display panel according to claim 1, wherein the display panel further comprises a pixel driving circuit and a light-emitting unit, and the pixel driving circuit is connected to a first electrode of the light-emitting unit;
wherein the display panel further comprises:
a common electrode layer, wherein the common electrode layer is used to form a second electrode of the light-emitting unit;
wherein the at least one first dummy line and the at least one second dummy line are connected to the common electrode layer.

12. The display panel according to claim 11, wherein the display panel further comprises a frame region around the display region, the frame region comprising a first frame region and a second frame region arranged opposite to each other in the first direction, and a third frame region and a fourth frame region arranged opposite to each other in the second direction;
wherein the display panel further comprises:
an electrode ring, wherein the electrode ring is located in the frame region and connected to the common electrode layer, at least partial structure of the electrode ring located in the first frame region is connected to one of the at least one first dummy line, at least partial structure of the electrode ring located in the second frame region is connected to the one of the at least one first dummy line, at least partial structure of the electrode ring located in the third frame region is connected to one of the at least one second dummy line, and at least partial structure of the electrode ring located in the fourth frame region is connected to one of the at least one second dummy line.

13. The display panel according to claim 1, wherein the minimum distance between orthographic projections of two adjacent first signal lines on the base substrate in the second direction is S5, and the maximum distance between the orthographic projections of two adjacent first signal lines on the base substrate in the second direction is S6, wherein (S6−S5)/S5 is greater than or equal to 0 and smaller than or equal to 0.2;
or, wherein the minimum distance between the orthographic projections of two adjacent second signal lines on the base substrate in the first direction is S7, and the maximum distance between the orthographic projections of two adjacent second signal lines on the base substrate in the first direction is S8, wherein (S8−S7)/S7 is greater than or equal to 0 and smaller than or equal to 0.2;
or, wherein the minimum distance between orthographic projections of two adjacent first signal lines on the base substrate in the second direction is S5, and the maximum distance between the orthographic projections of two adjacent first signal lines on the base substrate in the second direction is S6, wherein (S6−S5)/S5 is greater than or equal to 0 and smaller than or equal to 0.2, and wherein the minimum distance between the orthographic projections of two adjacent second signal lines on the base substrate in the first direction is S7, and the maximum distance between the orthographic projections of two adjacent second signal lines on the base substrate in the first direction is S8, wherein (S8−S7)/S7 is greater than or equal to 0 and smaller than or equal to 0.2.

14. The display panel according to claim 1, wherein the display panel further comprises a light-emitting unit and a pixel driving circuit for driving the light-emitting unit, the pixel driving circuit comprises a driving transistor, a fourth transistor, and a seventh transistor, a first electrode of the fourth transistor is connected to a data line, a second electrode of the fourth transistor is connected to a first electrode of the driving transistor, a first electrode of the seventh transistor is connected to a second initialization signal line, and a second electrode of the seventh transistor is connected to a first electrode of the light-emitting unit;
wherein the display panel further comprises:
an active layer between the base substrate and the pixel electrode layer, wherein the active layer comprises a seventh active portion and a fourth active portion, the seventh active portion is used to form a channel region of the seventh transistor, and the fourth active portion is used to form a channel region of the fourth transistor;
a first gate layer between the active layer and the pixel electrode layer, wherein the first gate layer comprises a second reset signal line, an orthographic projection of the second reset signal line on the base substrate covers an orthographic projection of the fourth active portion on the base substrate and an orthographic projection of the seventh active portion on the base substrate, a partial structure of the second reset signal line is used to form a gate of the seventh transistor, and a partial structure of the second reset signal line is used to form a gate of the fourth transistor.

15. The display panel according to claim 14, wherein the active layer further comprises:
a third active portion used to form a channel region of the driving transistor;
an eighth active portion connected to the fourth active portion;
a ninth active portion connected to the third active portion;
wherein the display panel further comprises:
a first source-drain layer between the first gate layer and the pixel electrode layer, wherein the first source-drain layer comprises a first bridging portion, and the first bridging portion is connected to the eighth active portion and the ninth active portion through via holes.

16. The display panel according to claim 1, wherein the display panel further comprises a pixel driving circuit, the pixel driving circuit comprises a driving transistor, a first transistor, and a second transistor, a first electrode of the first transistor is connected to a first initialization signal line, a second electrode of the first transistor is connected to a gate of the driving transistor, a first electrode of the second transistor is connected to the gate of the driving transistor, and a second electrode of the second transistor is connected to a second electrode of the driving transistor;
wherein the display panel further comprises:
an active layer between the base substrate and the pixel electrode layer, wherein the active layer comprises a first active portion, a tenth active portion, a first active sub-portion, a second active sub-portion, and a third active sub-portion connected between the first active sub-portion and the second active sub-portion, the first active portion is used to form a channel region of the first transistor, the first active sub-portion and the second active sub-portion are used to form a channel region of the second transistor, and the tenth active portion is connected between the first active portion and the first active sub-portion;
a second gate layer between the active layer and the pixel electrode layer, wherein the second gate layer comprises the first initialization signal line, a first protrusion, and a second protrusion, the first protrusion is connected to the first initialization signal line, and the second protrusion is connected to the first initialization signal line;
wherein an orthographic projection of the first protrusion on the base substrate at least partially overlaps with an orthographic projection of the third active sub-portion on the base substrate, and an orthographic projection of the second protrusion on the base substrate at least partially overlaps with the orthographic projection of the tenth active portion on the base substrate.

17. A display panel, wherein a display region of the display panel comprises a fan-out region and a normal display region outside the fan-out region, and the display panel further comprises:
a base substrate;
a plurality of data lines located in the display region, wherein orthographic projections of the data lines on the base substrate are spaced apart along a first direction and extend along a second direction, and the first direction intersects the second direction;
a plurality of first signal lines, wherein orthographic projections of the first signal lines on the base substrate extend along the first direction and are spaced apart along the second direction, a part of the first signal lines located in the fan-out region form at least one first data fan-out line, and at least one first signal line located in the normal display region forms at least one first dummy line, one of the at least one first data fan-out line is arranged in correspondence with a corresponding data line in the plurality of data lines, and the one of the at least one first data fan-out line is connected to the corresponding data line which corresponds to the one of the at least one first data fan-out line;
a plurality of second signal lines located in a different conductive layer from the first signal lines, wherein orthographic projections of the second signal lines on the base substrate extend along the second direction and are spaced apart along the first direction, a part of the second signal lines located in the fan-out region forms at least one second data fan-out line, and at least one second signal line located in the normal display region forms at least one second dummy line, the one of the at least one second data fan-out line is arranged in correspondence with a corresponding first data fan-out line, and the one of the at least one second data fan-out line is connected to the corresponding first data fan-out line;
a plurality of first interconnection portions located in the normal display region, wherein one of the first interconnection portions is connected between a first dummy line and a second dummy line, and an orthographic projection of the first dummy line on the base substrate interests an orthographic projection of the second dummy line on the base substrate; and
wherein the display panel further comprises pixel driving circuits, and in the normal display region, a part of the pixel driving circuits is correspondingly provided with one first interconnection portion; and
wherein n pixel driving circuits which are adjacent in the first direction are correspondingly provided with m first interconnection portions;
where n is a positive integer greater than or equal to 2, m is a positive integer greater than or equal to 1, and n is greater than m.

18. The display panel according to claim 17, wherein n is equal to 4, m is equal to 3, the first direction is a row direction, and the second direction is a column direction;
wherein the display panel further comprises:
a pixel electrode layer comprising a plurality of electrode portions, wherein the plurality of electrode portions comprise a first electrode portion, a second electrode portion, a third electrode portion, and a fourth electrode portion;
wherein among a plurality of electrode portions connected to pixel driving circuits in a same row, the first electrode portion, the second electrode portion, the third electrode portion, and the fourth electrode portion are alternately distributed in sequence in the row direction;
wherein in two adjacent columns of pixel driving circuits, the first electrode portion and the third electrode portion are connected to a same column of pixel driving circuits, and the first electrode portion and the third electrode portion connected to the same column of pixel driving circuits are alternately distributed in sequence in the column direction, the second electrode portion and the fourth electrode portion are connected to another column of pixel driving circuits, and the second electrode portion and the fourth electrode portion connected to a same column of pixel driving circuits are alternately distributed in sequence in the column direction;
wherein among four pixel driving circuits which are adjacent in the first direction, a pixel driving circuit corresponding to the first electrode portion is correspondingly provided with one of the first interconnection portions, a pixel driving circuit corresponding to the second electrode portion is correspondingly provided with another one of the first interconnection portions, and a pixel driving circuit corresponding to the third electrode portion is correspondingly provided with a further one of the first interconnection portions.

19. The display panel according to claim 17, wherein the pixel driving circuit comprises a driving transistor, a second transistor and a fifth transistor, a first electrode of the second transistor is connected to a gate of the driving transistor, a second electrode of the second transistor is connected to a second electrode of the driving transistor, a first electrode of the fifth transistor is connected to a power supply line, and a second electrode of the fifth transistor is connected to a first electrode of the driving transistor;
wherein the display panel further comprises:
a first gate layer located at a side of the base substrate, wherein the first gate layer comprises a first conductive portion and a gate line, an orthographic projection of the gate line on the base substrate extends along the first direction, the first conductive portion is used to form the gate of the driving transistor, and a partial structure of the gate line is used to form a gate of the second transistor;
a second source-drain layer located at a side of the first gate layer away from the base substrate, wherein the second source-drain layer comprises the power supply line and the data line, and an orthographic projection of the power supply line on the base substrate and the orthographic projection of the data line on the base substrate extend along the second direction;
wherein one of the at least one first dummy line is arranged in correspondence with a pixel driving circuit, and in the pixel driving circuit and the one of the at least one first dummy line which mutually correspond to each other, an orthographic projection of the one of the at least one first dummy line on the base substrate is located at a side of an orthographic projection of the first conductive portion on the base substrate away from an orthographic projection of the gate line on the base substrate;
wherein one of the at least one second dummy line is arranged in correspondence with a pixel driving circuit, and in the pixel driving circuit and one of the at least one second dummy line which mutually correspond to each other, an orthographic projection of the one of the at least one second dummy line on the base substrate is located at a side of the orthographic projection of the power supply line on the base substrate away from an orthographic projection of the data line on the base substrate;
wherein one of the first interconnection portions is arranged in correspondence with a first dummy line and a second dummy line which are directly connected to the one of the first interconnection portions, and a pixel driving circuit corresponding to a same group of the first dummy line and the second dummy line is arranged in correspondence with the one of the first interconnection portions.

20. A display apparatus, comprising a display panel;
wherein a display region of the display panel comprises a fan-out region and a normal display region outside the fan-out region, and the display panel further comprises:
a base substrate;
a plurality of data lines located in the display region, wherein orthographic projections of the data lines on the base substrate are spaced apart along a first direction and extend along a second direction, and the first direction intersects the second direction;
a plurality of first signal lines, wherein orthographic projections of the first signal lines on the base substrate extend along the first direction and are spaced apart along the second direction, a part of the first signal lines located in the fan-out region form at least one first data fan-out line, and at least one first signal line located in the normal display region forms at least one first dummy line, one of the at least one first data fan-out line is arranged in correspondence with a corresponding data line in the plurality of data lines, and the one of the at least one first data fan-out line is connected to the corresponding data line which corresponds to the one of the at least one first data fan-out line;
a plurality of second signal lines located in a different conductive layer from the first signal lines, wherein orthographic projections of the second signal lines on the base substrate extend along the second direction and are spaced apart along the first direction, a part of the second signal lines located in the fan-out region forms at least one second data fan-out line, and at least one second signal line located in the normal display region forms at least one second dummy line, one of the at least one second data fan-out line is arranged in correspondence with a corresponding first data fan-out line, and the one of the at least one second data fan-out line is connected to the corresponding first data fan-out line;
a plurality of first interconnection portions located in the normal display region, wherein one of the plurality of first interconnection portions is connected between a first dummy line and a second dummy line, and an orthographic projection of the first dummy line on the base substrate interests an orthographic projection of the second dummy line on the base substrate; and
a pixel electrode layer comprising a plurality of electrode portions, wherein orthographic projections of the electrode portions on the base substrate do not overlap with orthographic projections of the first interconnection portions on the base substrate.
